(19) United States
(12) Patent Application Publication
(10) Pub. No.: US 2015/0256734 A1
(43) Pub. Date: Sep. 10, 2015

(54) IMAGING APPARATUS

(71) Applicant: SONY CORPORATION, Tokyo (JP)

(72) Inventor: Takahiro FUKUHARA, Kanagawa (JP)

(73) Assignee: SONY CORPORATION, Tokyo (JP)

(21) Appl. No.: 14/608,778

(22) Filed: Jan. 29, 2015

(30) Foreign Application Priority Data
Mar. 5, 2014 (JP) 2014-042855
Sep. 16, 2014 (JP) 2014-188275

(51) Int. Cl. H04N 5/235; H01L 27/146; H04N 5/335; H04N 5/225

(52) U.S. Cl. CPC H04N 5/2355; H04N 5/2254; H01L 27/14627; H04N 5/335

(57) ABSTRACT

An imaging apparatus includes an imaging lens; an imaging element which performs a photoelectric conversion with respect to light which is condensed using the imaging lens; and lens arrays which are configured by arranging micro lenses of which exposure conditions are different on a two-dimensional plane, are arranged by being separated on a front face of an imaging face of the imaging element, and causes light which is output from each micro lens to be formed as an image on the imaging face of the imaging element.

### CROSS REFERENCE TO RELATED APPLICATIONS

This application claims the benefit of Japanese Priority Patent Application JP 2014-042855 filed Mar. 5, 2014, and Japanese Priority Patent Application JP 2014-188275 filed Sep. 16, 2014, the entire contents of each of which are incorporated herein by reference.

### BACKGROUND

The present technology which is disclosed in the specification relates to an imaging apparatus which images a high dynamic range image using an imaging element with a low dynamic range.

Due to a high bit of an imaging element (image sensor), a correspondence to a high bit in a display, or the like, a high dynamic range (HDR) of an image is progressing. In an HDR image, a contrast ratio of a color with maximum brightness to a color with minimum brightness reaches 10000:1 or greater, for example, and it is possible to realistically express the real world. In the HDR image, there are advantage that it is possible to realistically express shade, simulate an exposure, express glare, and the like.

As a field of application of the HDR technology, there are an instrument or a device in which an image which is captured from a complementary metal oxide semiconductor (CMOS), or a charge coupled device ((CCD) sensor) is used, a digital still camera, a camcorder for a moving image, a camera for a medical image, a surveillance camera, a digital camera for cinema-photography, a camera for a binocular image, a display, and the like.

Various technologies for imaging a high dynamic range image using an imaging element for a low dynamic range have been proposed.

For example, an imaging apparatus in which an HDR image is composited from a plurality of imaged images of which exposure amounts are different has been proposed (for example, refer to Japanese Unexamined Patent Application Publication No. 2013-255201). However, when an HDR image of one frame is composited from a plurality of frames, there are the following problems.

(1) Memories of a plurality of frames are necessary

(2) Delay time due to photographing and processing of plurality of frames

(3) Motion blur in moving object

In addition, an imaging apparatus in which a mask plate which is formed of a two-dimensional array of cells of which degrees of transparency corresponding to an exposure value are different is placed before an image sensing device, imaging is performed using a mechanism in which exposures are different in each pixel in one frame, and an image signal in a high dynamic range is generated by performing a predetermined image processing with respect to the obtained image signal has been proposed (for example, refer to Japanese Patent No. 4494690).

On the other hand, as a technology of obtaining image signals of which properties or imaging conditions are different from one frame, a technology of light field photography (LDF) is known. In an imaging apparatus in which the LFP is used, a lens array is arranged between an imaging lens and an image sensor. An input ray from an object is divided into rays of each viewpoint in the lens array, and is received in the image sensor thereafter. Multiple viewpoint images are generated at the same time using pixel data which is obtained from the image sensor (for example, refer to Japanese Unexamined Patent Application Publication No. 2010-154493, and “Light Field Photography with a Hand-Held Plenoptic Camera” (Stanford Tech Report CTSR 2005-02) written by Ren. Ng, et al.

In the technology of LFP, viewpoints are divided using a lens array, and multiple viewpoint images are generated in one frame. Specifically, in an imaging apparatus in which the technology of LFP is used, a ray which penetrates one lens of the lens array is received in m×n pixels (here, m and n are integers of one or more, respectively) on the image sensor. That is, it is possible to obtain viewpoint images of pixels (pixels of m×n) corresponding to each lens. When such a property of the imaging apparatus in which the technology of LFP is used is used, it is possible to generate a parallax image in each viewpoint in the left and right directions among other viewpoints of which phase differences are different. That is, it is possible to execute a view of a stereoscopic image in which binocular parallax is used.

### SUMMARY

It is desirable to provide an excellent imaging apparatus in which imaging of a high dynamic range image is performed using an imaging element for a low dynamic range.

According to an embodiment of the present technology, there is provided an imaging apparatus which includes an imaging lens; an imaging element which performs a photoelectric conversion with respect to light which is condensed using the imaging lens; and lens arrays which are configured by arranging micro lenses of which exposure conditions are different on a two-dimensional plane, are arranged by being separated on a front face of an imaging face of the imaging element, and causes light which is output from each micro lens to be formed as an image on the imaging face of the imaging element.

The imaging apparatus may further include an image composition unit which composites a plurality of imaged images which are output from the imaging element, and of which exposure conditions are different, and generates a high dynamic range image.

In the imaging apparatus, the lens array may include a micro lens with a property of a low exposure lens, and a micro lens with a property of a high exposure lens. In addition, the imaging element may photograph a low exposure image and a high exposure image by respectively performing a photoelectric conversion, with respect to output light of each micro lenses with the property of the low exposure lens, and the property of the high exposure lens, and the image composition unit may generate a high dynamic range image by compositing the low exposure image and the high exposure image.

In the imaging apparatus, the lens array may include micro lenses of three or more types of which exposure lens properties are different. In addition, the imaging element may photograph images of three types or more of which exposure conditions are different by performing a photoelectric conversion, respectively, with respect to output light of a micro lens with each exposure lens property, and the image composition unit may generate a high dynamic range image by compositing imaged images of three types or more of which the exposure conditions are different.

The imaging apparatus may further include an interpolation unit which improves resolution by interpolating pixels at a pixel position with another exposure condition using a pixel value of neighboring pixels with the same exposure condition with respect to respective imaged images of which exposure conditions are different, after the images are formed in the imaging element.

In the imaging apparatus, the interpolation unit may improve resolution of respective imaged images of which exposure conditions are different so as to be the same resolution as that of an input image using the pixel interpolation.

In the imaging apparatus, the micro lens may include a diaphragm for controlling a light intensity which meets a corresponding exposure condition.

According to another embodiment of the present technology, there is provided an imaging apparatus which includes an imaging lens; an imaging element which performs photoelectric conversion with respect to light which is condensed using the imaging element: lens arrays which are configured by being arranged with a plurality of micro lenses to which m×n pixels of the imaging element are respectively allocated on a two-dimensional plane, and are arranged by being separated on a front face of an imaging face of the imaging element; and an image composition unit which composites at least part of image data among m×n pixels which receive light which has passed through each micro lens of the lens array.

In the imaging apparatus, the image composition unit may generate a stereoscopic image based on at least part of image data among the m×n pixels which receive light which has passed through each micro lens of the lens array.

In the imaging apparatus, the image composition unit may composite a left eye image based on image data which is read from a pixel which receives a ray for a left eye which passes through each micro lens, and may composite a right eye image based on image data which is read from a pixel which receives a ray for a right eye.

In the imaging apparatus, the image composition unit may generate a plurality of images of which exposure conditions are different at the same time based on at least part of image data among m×n pixels which receive light which has passed through each micro lens of the lens array.

In the imaging apparatus, the image composition unit may generate a low exposure image based on image data which is read from a pixel which is set to a low exposure condition among m×n pixels which receive light which has passed through each micro lens, and generate a high exposure image based on image data which is read from a pixel which is set to a high exposure condition simultaneously with the low exposure image.

In the imaging apparatus, the image composition unit may generate a stereoscopic image, a low exposure image, and a high exposure image at the same time based on at least part of image data among m×n pixels which receive light which has passed through each micro lens of the lens array.

In the imaging apparatus, the image composition unit may generate a high dynamic range image by compositing the low exposure image and the high exposure image which are generated at the same time.

In the imaging apparatus, the imaging element may be arranged in a state in which a pixel group which is arranged in a square lattice shape along a horizontal direction and a vertical direction is rotated by a predetermined angle in a light receiving plane.

In the imaging apparatus, an exposure time of each pixel may be controlled so as to have a light intensity which meets each exposure condition.

In the imaging apparatus, an amount of narrowing of light which is input to each pixel may be controlled so as to be a light intensity which meets each exposure condition.

The imaging apparatus may further include an encoding unit which outputs a code stream by encoding an image which is generated in the image composition unit.

In the imaging apparatus, generating either a stereoscopic image or a high dynamic range image may be selected based on instructed information, and the encoding unit may output an encoding result of the stereoscopic image when the generating of the stereoscopic image is selected, and output an encoding result of the high dynamic range image when the generating of the high dynamic range image is selected.

In the imaging apparatus, the encoding unit may include a tone mapping unit which performs tone mapping with respect to a high dynamic range image when the high dynamic range image is encoded; a first encoding unit which encodes the image after being subjected to the tone mapping; a decoding unit which decodes an encoding result using the first encoding unit; a reverse tone mapping unit which performs reverse tone mapping with respect to the decoding result using the decoding unit; a difference calculation unit which calculates a difference between the original high dynamic range image and an image which is subjected to the reverse tone mapping; and a second encoding unit which encodes a difference image using the difference calculation unit.

According to the technology which is disclosed in the specification, it is possible to provide an excellent imaging apparatus in which a high dynamic range image is imaged using an imaging element of a low dynamic range.

According to the technology which is disclosed in the specification, since a high dynamic range image is generated from an image of one frame using an imaging element of a low dynamic range, it is possible to solve problems in a memory, delay, and motion blur of a moving object in a case of generating a high dynamic range image from a plurality of frames.

According to the technology which is disclosed in the specification, when a plurality of exposure images of which exposure conditions are different are obtained at the same point of time, by arranging a lens array according to the LFP technology on the front face of the imaging element, and controlling rays which pass through each micro lens of the lens array so as to be output in different exposure conditions, it is possible to generate a high dynamic range image in one frame by compositing the plurality of exposure images. According to the technology which is disclosed in the specification, since a process of generating a high dynamic range image is completed in one frame, it is possible to save a frame memory, and it is also possible to solve a problem of motion blur of a moving object since a delay time is shortened. In addition, according to the technology which is disclosed in the specification, it is possible to generate a stereoscopic image using binocular parallax using a principle of the LFP.

In addition, the effect which is disclosed in the specification is merely an example, and the effect of the present technology is not limited to this. In addition, there is a case in which the present technology exhibits another additional effect, in addition to the above described effect.

Further, another object, property, or advantage of the technology which is disclosed in the specification will be clarified using detailed descriptions based on embodiments which will be described later, or based on accompanying drawings.

### BRIEF DESCRIPTION OF THE DRAWINGS

FIG. 1 is a diagram which conceptually illustrates an imaging apparatus according to a first embodiment of the present technology which is disclosed in the specification.

FIG. 2 is a diagram which conceptually illustrates a modification example of an imaging apparatus according to a second embodiment of the present technology which is disclosed in the specification.

FIG. 3 is a diagram which illustrates a configuration example of an imaging unit which is illustrated in FIG. 1.

FIG. 4 is a diagram which illustrates an imaging face of an imaging element.

FIG. 5 is a diagram which illustrates a state in which interpolation processing of an L component pixel is performed.

FIG. 6 is a diagram which illustrates a state in which interpolation processing of an H component pixel is performed.

FIG. 7 is a diagram which illustrates a state in which a L component image and an H component image with the same resolution as that of the original image are generated by performing interpolation processing in both the L component pixel and the H component pixel.

FIG. 8 is a diagram which illustrates a configuration example of an imaging unit which is illustrated in FIG. 2.

FIG. 9 is a diagram which illustrates an imaging face of the imaging element.

FIG. 10 is a diagram which illustrates a state in which an L component image, an M component image, and an H component image with the same resolution as that of the original image are generated by performing interpolation processing with respect to each of an L component pixel, an M component pixel, and an H component pixel.

FIG. 11 is a diagram in which a diaphragm window (case in which a pixel is set to an amount of high exposure by setting an amount of narrowing to be small) is exemplified.

FIG. 12 is a diagram in which a diaphragm window (case in which a corresponding pixel is set to an amount of middle exposure by setting amount of narrowing to be of a medium degree) is exemplified.

FIG. 13 is a diagram in which a diaphragm window (case in which a corresponding pixel is set to an amount of low exposure by setting amount of narrowing to be large) is exemplified.

FIG. 14 is a diagram which illustrates the entire configuration of an imaging apparatus according to a second embodiment of the technology which is disclosed in the specification.

FIG. 15 is a diagram which illustrates an arranging example of a lens array and an imaging element.

FIG. 16 is a diagram which illustrates a pixel array (diagonal array) of the imaging element.

FIG. 17 is a diagram which illustrates an example of a pixel array in which pixels are in a state arranged in a square which is normal.

FIG. 18 is a diagram which illustrates a state in which image data of a parallax image is read from a pixel group which is diagonally arranged.

FIG. 19 is a diagram which illustrates a state in which image data of a parallax image is read from a pixel group which is arranged in a square.

FIG. 20 is a diagram which illustrates a configuration example (case of square array) of an imaging element in which each micro lens performs separating of left and right parallax by applying the LFP technology.

FIG. 21 is a diagram which describes a mechanism in which a parallax image is obtained by performing separating of left and right parallax of a micro lens from a division pixel of each pixel of an imaging element which is diagonally arranged, by applying the LFP technology.

FIG. 22 is a diagram which conceptually illustrates a pixel array of the imaging element which is illustrated in FIG. 21.

FIG. 23 is a diagram which describes a mechanism in which a parallax image is obtained by performing separating of left and right parallax of a micro lens from each division pixel of 2×2 pixels of the imaging element which are diagonally arranged, by applying the LFP technology.

FIG. 24 is a diagram which describes a mechanism in which image data items of a low exposure time (Se) and a long exposure time (Le) are obtained from a division pixel of each pixel of the imaging element which is diagonally arranged, by applying the LFP technology.

FIG. 25 is a diagram which describes a mechanism in which image data items of a low exposure time (Se) and a long exposure time (Le) are obtained from each division pixel of 2×2 pixels of the imaging element which are diagonally arranged, by applying the LFP technology.

FIG. 26 is a diagram which describes a mechanism in which a stereoscopic image of a high dynamic range is obtained from imaging elements which are diagonally arranged, by applying the LFP technology.

FIG. 27 is a diagram which illustrates a modification example in FIG. 26.

FIG. 28 is a diagram which illustrates a configuration example of an image compression device which compresses a high dynamic range image.

FIG. 29 is a diagram which illustrates a configuration example of an image decoding device which decodes a compression image which is output from the image compression device.

FIG. 30 is a diagram which illustrates a configuration example of an image compression device which compresses a stereoscopic image of a high dynamic range.

FIG. 31 is a diagram which illustrates a configuration example of an image decoding device which decodes a compressed stereoscopic image which is output from the image compression device.

### DETAILED DESCRIPTION OF EMBODIMENTS

Hereinafter, embodiments of the technology which is disclosed in the specification will be described in detail with reference to drawings.

### First Embodiment

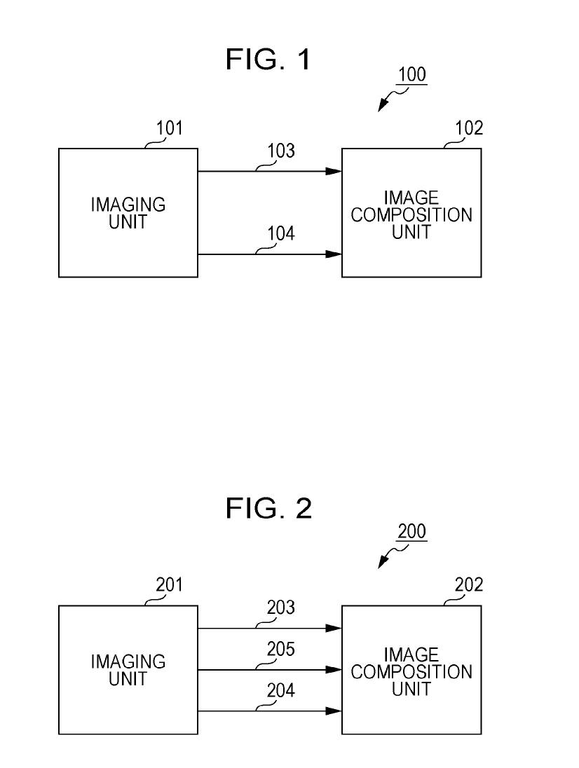

FIG. 1 conceptually illustrates an imaging element 100 according to a first embodiment of the technology which is disclosed in the specification.

An imaging unit 101 outputs one frame including an image signal 103 with a high exposure amount and an image signal 104 with a low exposure amount in one imaging process. In addition, an image composition unit 102 composites the image signal 103 with the high exposure amount and the image signal 104 with the low exposure amount, and generates an HDR image using imaging of one frame, that is, in one imaging process. A difference in exposure conditions such as the high exposure amount or the low exposure amount is controlled using an exposure time in each pixel, an amount of narrowing a diaphragm window at a time of exposure, or the like.

In addition, in FIG. 2, a modification example 200 of the imaging apparatus according to the first embodiment of the technology which is disclosed in the specification is conceptually illustrated.

The imaging unit 201 outputs one frame including an image signal 203 with a high exposure amount, an image signal 204 with a low exposure amount, and an image signal 205 with a medium exposure amount in one imaging process. In addition, an image composition unit 202 composites the image signal 203 with the high exposure amount, the image signal 204 with the low exposure amount, and the image signal 205 with the medium exposure amount signal, and generates an HDR image using imaging of one frame, that is, in one imaging process. A difference in exposure conditions such as the high exposure amount or the low exposure amount is controlled using an exposure time in each pixel, an amount of narrowing of a diaphragm window at a time of exposure, or the like.

As a technology of obtaining image signals of which properties or exposure conditions are different from one frame, a light field photography (LFP) technology is known. In an imaging apparatus in which the LFP technology is used, a lens array is arranged between an imaging lens and an imaging sensor. An input ray from an object is divided into rays of each viewpoint in the lens array, and is received in the image sensor thereafter. In addition, a multi viewpoint image is generated at the same point of time using image data which is obtained from the image sensor (for example, refer to Japanese Unexamined Patent Application Publication No. 2010-154493, and “Light Field Photography with a Hand-Held Plenoptic Camera” (Stanford Tech Report CTSR 2005-02) written by Ren. Ng, etc.).

In the LFP technology, viewpoints are divided using the lens array, and images of a plurality of viewpoints are generated in one frame. In contrast to this, in the first embodiment, a point of arranging the lens array on the front face of an imaging element face of the imaging unit 101 (or 201) is the same as an LFP in the related art; however, the first embodiment is different from the related art in a point in which images of which exposure amounts are different are generated in one frame by using a lens array in which micro lenses of which exposure properties are different are combined. In addition, according to the embodiment it is possible to generate an HDR image from one frame by compositing images of which exposure amounts are different.

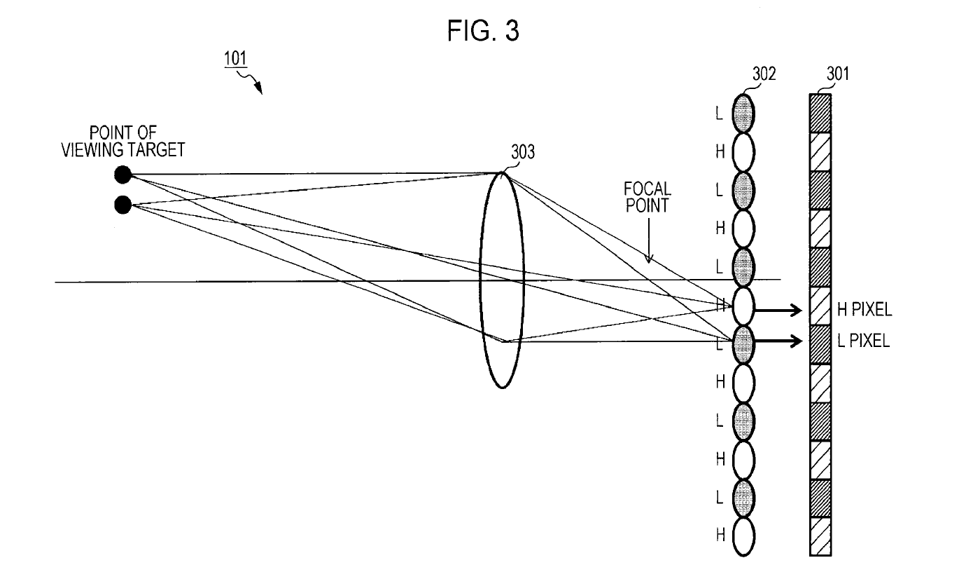

FIG. 3 illustrates a configuration example of the imaging unit 101 which is illustrated in FIG. 1. As illustrated, the imaging unit 101 is configured by applying the LFP technology, and a lens array 302 is arranged on the front face of an imaging face of an imaging element 301. The lens array 302 is configured by alternately arranging micro lenses on a two-dimensional plane, and the micro lenses are arranged at an interval in an optical axis direction with respect to a focal plane of an imaging lens 303. Specifically, the lens array 302 is arranged on the focal plane (image forming plane) of the imaging lens 303, and the imaging element 301 is arranged at a focal position of the micro lens of the lens array 302.

According to the embodiment, the lens array 302 is configured by alternately arranging two types of micro lenses of an L lens with a property of a low exposure lens, and an H lens with a property of a high exposure lens on a two-dimensional plane. In addition, the lens array has a configuration in which one micro lens is provided with respect to one pixel of the imaging element 301 (that is, one to one correspondence of pixel and micro lens), and each pixel is irradiated with light which passes through a corresponding micro lens. Accordingly, imaged images of the L lens and the H lens are respectively input to pixels on the imaging element 301, and a photoelectric conversion is performed. As a result, a high exposure pixel signal 103 is output from an H pixel irradiated with light which has passed through the H lens, and a low exposure pixel signal 104 is output from an L pixel irradiated with light which has passed through the L lens.

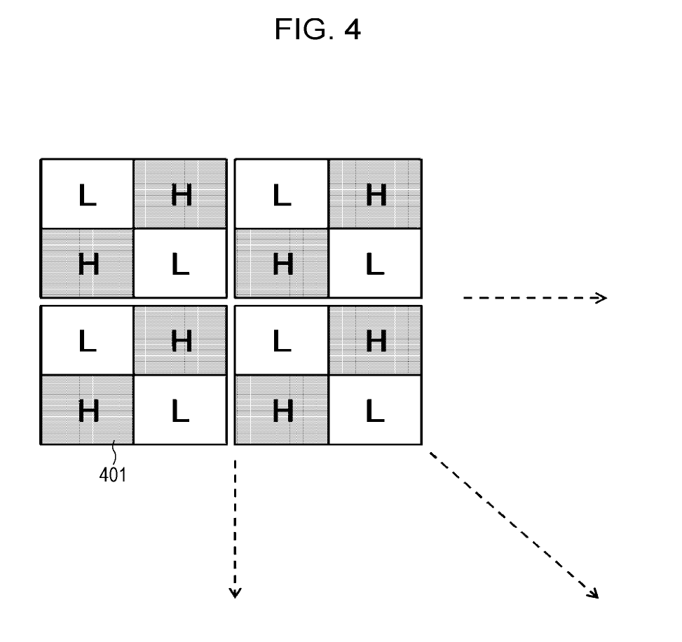

FIG. 4 illustrates an imaging face 401 of the imaging element 301. As illustrated, an H pixel and an L pixel are alternately arranged in the horizontal direction and the vertical direction on a two-dimensional plane. A dynamic range is improved since a high exposure pixel signal and a low exposure pixel signal are included in one frame. However, it is also understood from FIG. 4 that resolution of both a high exposure image and a low exposure image which are obtained from the imaging element 301 in one frame, that is, in one photographing, decreases by a half with respect to the original image. That is why a dynamic range is improved, but resolution decreases.

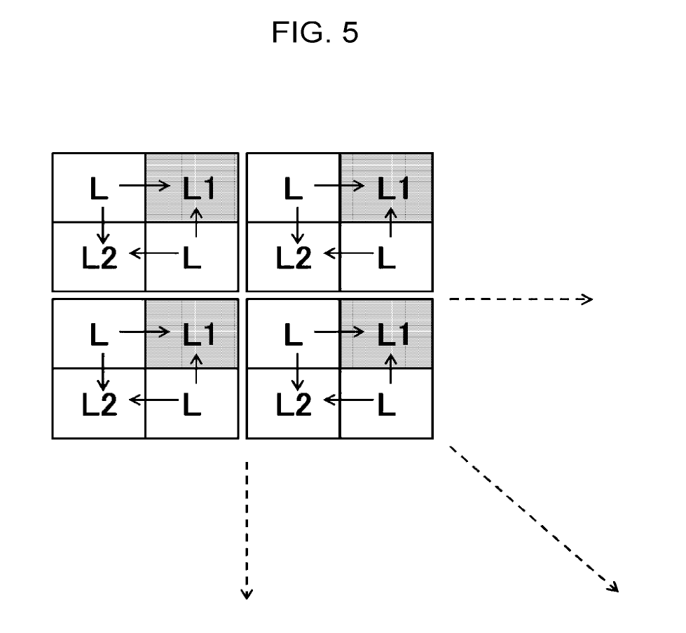

Therefore, in the imaging unit 101, new L component pixels L1 and L2 are generated at positions of H component pixels, originally, due to interpolation processing (for example, calculating of mean value) for neighboring L component pixels with respect to an imaged image which is output from the imaging element 301. In this manner, it is possible to increase a compensation effect, and to maintain the original resolution of an input image as well, using the unit, since values of neighboring pixels are similar, though the L component pixel does not practically exist. FIG. 5 illustrates a state in which interpolation processing of the L component pixel is performed.

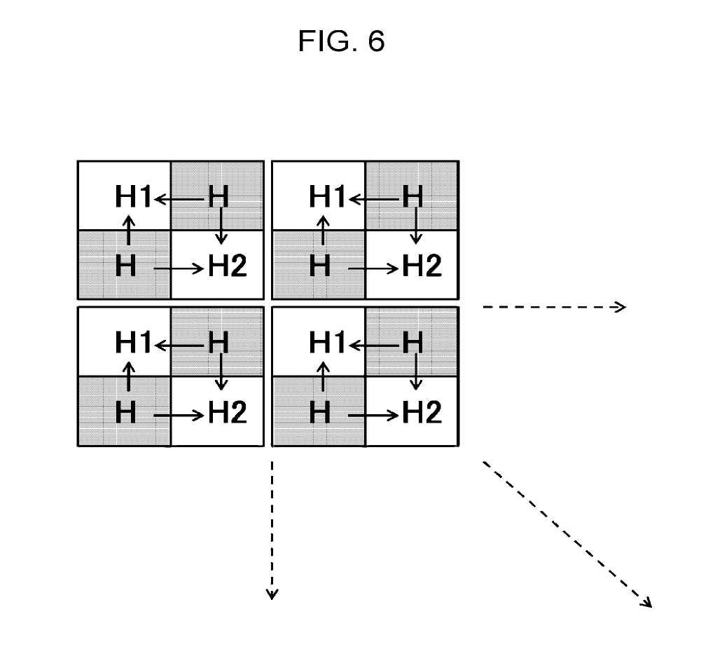

In addition, as illustrated in FIG. 6, with respect to the H component pixel, similarly, new H component pixels H1 and H2 are generated at positions of L component pixels, originally, using interpolation processing (for example, calculation of mean value) of neighboring H component pixels. In this manner, it is possible to increase a compensation effect, and to maintain the original resolution of the input image, as well, using the unit, since values of neighboring pixels are usually similar, though the H component pixel does not practically exist.

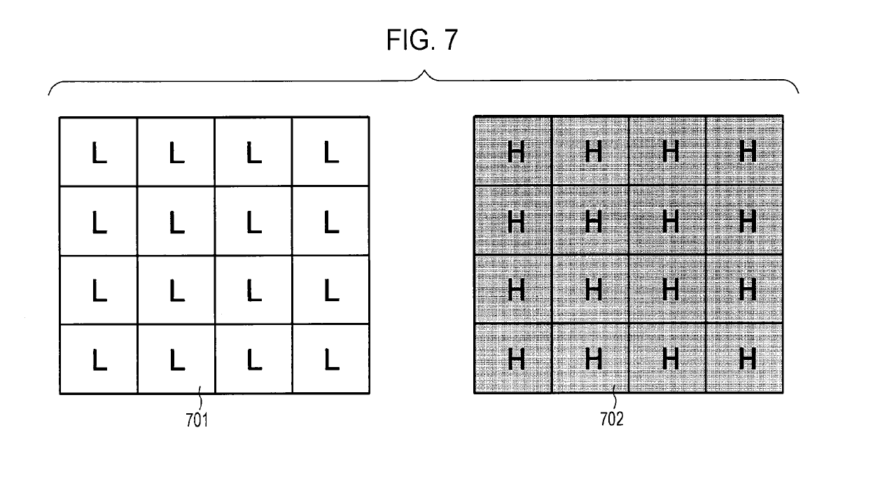

As illustrated in FIGS. 5 and 6, when interpolation processing of neighboring pixels with the same component is performed at pixel positions of another component with respect to both the L component pixel and the H component pixel, an L component image 701 and an H component image 702 with the same resolution as that of the original image are generated, as illustrated in FIG. 7.

The image composition unit 102 is capable of generating a high dynamic range image in which halation, black crush, or the like does not occur by compositing the two images 701 and 702. However, a couple of methods in which a high dynamic range image is generated by compositing a plurality of images of which exposure properties are different have already been used in the industry, and the embodiment is not limited to a specific image compositing method. In general, an image processing method in which a dynamic range is improved in the entire image, while reducing halation of an image in the image with a high exposure amount, and solving a problem of black crush in a low exposure amount has been used.

In the examples illustrated in FIGS. 1 and 3, images which are photographed under two types of exposure condition using the lens array 302 with two types of exposure property are generated, and a high dynamic range image is composited. In addition, in order to composite a high dynamic range image with a higher quality, it is effective when an image which is photographed under exposure conditions of three types or more is generated.

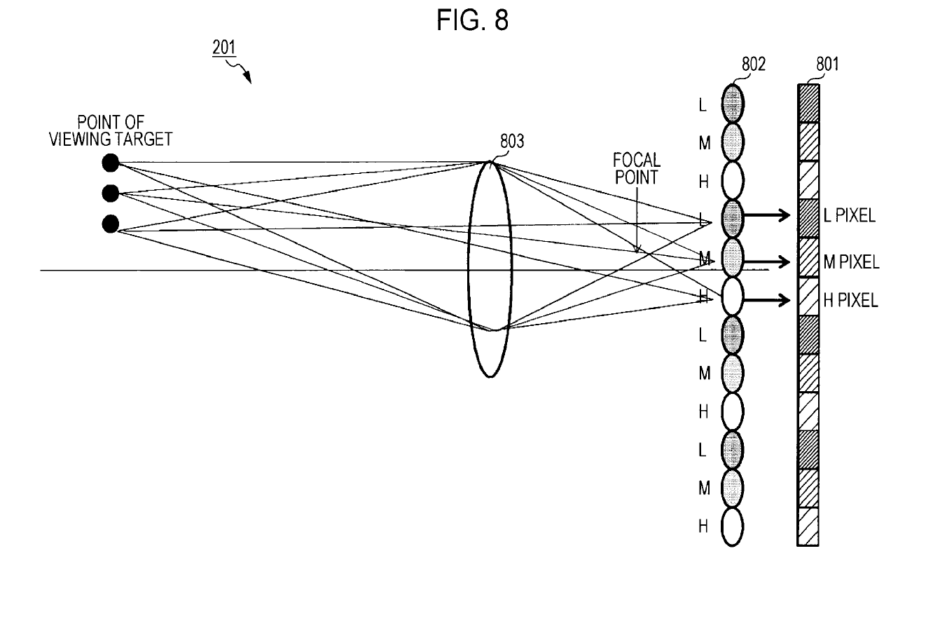

FIG. 8 illustrates a configuration example of the imaging unit 201 which is illustrated in FIG. 2. As illustrated, a lens array 802 is arranged on the front face of an imaging face of an imaging element 801 of the imaging unit 201. The lens array 802 is configured by alternately arranging micro lenses on a two-dimensional plane, and the micro lenses are arranged with an interval in an optical axis direction with respect to a focal plane of an imaging lens 803. Specifically, the lens array 802 is arranged on a focal plane (image forming plane) of the imaging lens 801, and the imaging element 801 is arranged at a focal position of the micro lens of the lens array 802.

According to the embodiment, the lens array 802 is configured by alternately arranging three types of micro lenses of an L lens with a property of a low exposure lens, an H lens with a property of a high exposure lens, and an M lens with a property of a medium exposure lens on a two-dimensional plane. In addition, the lens array has a configuration in which one micro lens is arranged with respect to one pixel of the imaging element 801 (that is, one to one correspondence of pixel and micro lens), and each pixel is irradiated with light which has passed through a corresponding micro lens. Accordingly, imaged images of the L lens and the H lens are respectively input to pixels on the imaging element 801, and photoelectric conversion is performed. As a result, a high exposure pixel signal 203 is output from an H pixel which is irradiated with light which has passed through the H lens, a low exposure pixel signal 204 is output from an L pixel which is irradiated with light which has passed through the L lens, and a medium exposure pixel signal 205 is output from an M pixel which is irradiated with light which has passed through the M lens.

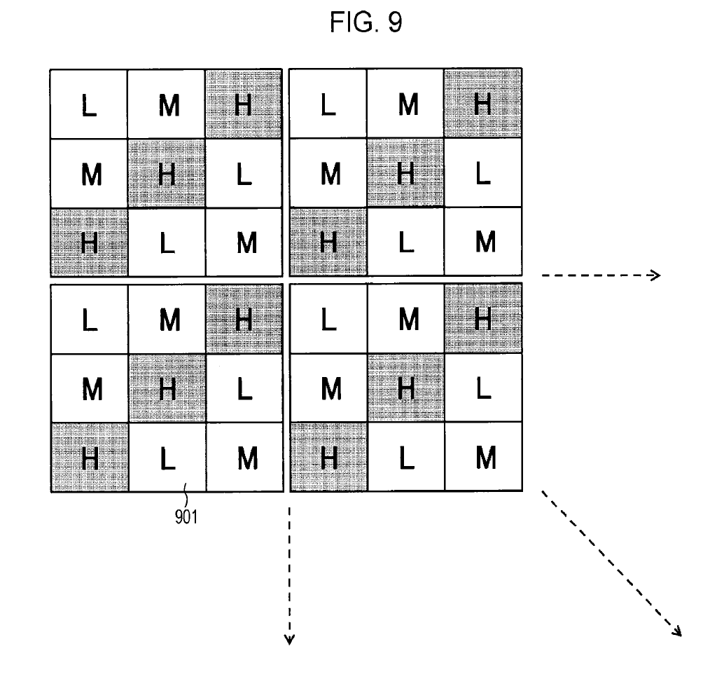

FIG. 9 illustrates an imaging face 901 of the imaging element 801. As illustrated, an H pixel, an M pixel, and an L pixel are arranged in order in the horizontal direction and the vertical direction on a two-dimensional plane. Since a high exposure pixel signal, a medium exposure pixel signal, and a low exposure pixel signal are included in one frame, a dynamic range is further improved compared to the example illustrated in FIG. 4. However, it is also understood from FIG. 9 that resolution of all of a high exposure image, a medium exposure image, and a low exposure image which are obtained from the imaging element 801 in one frame, that is, in one photographing process, decreases by a third with respect to the original image.

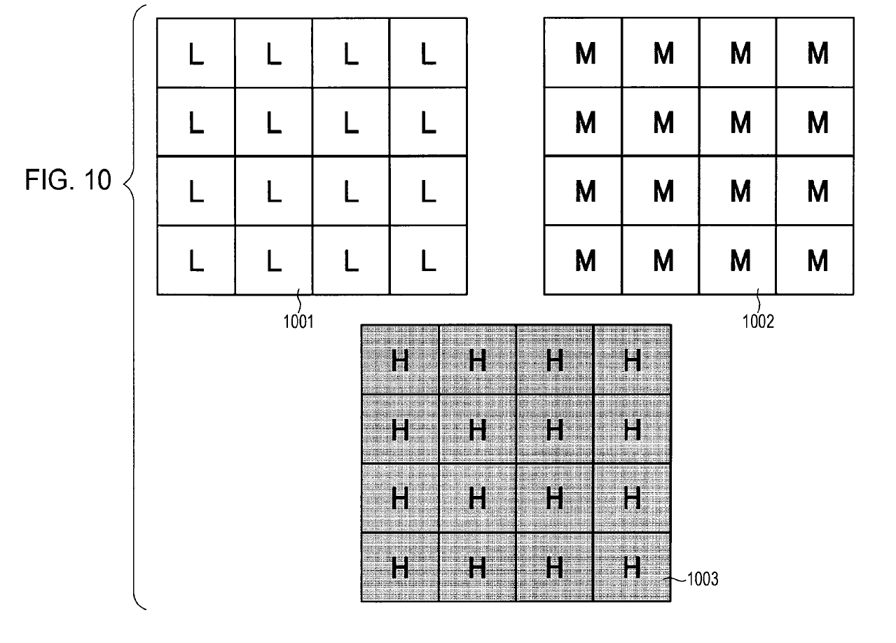

Therefore, in the imaging unit 201, interpolation processing of neighboring pixels with the same component is performed at a pixel position of another component in each of the L component pixel, the M component pixel, and the H component pixel with respect to an imaged image which is output from the imaging element 801. In this manner, since values of neighboring pixels are usually similar, though it is a pixel with another component which does not exist practically, it is possible to increase a compensation effect, and maintain the original resolution of an input image as well, using the unit. FIG. 10 illustrates a state in which an L component image 1001, an M component image 1002, and an H component image 1003 with the same resolution as that of the original image are generated by performing interpolation processing with respect to each of the L component pixel, the M component pixel, and the H component pixel.

The image composition unit 202 is capable of generating an image of a higher dynamic range in which halation, black crush, or the like does not occur by compositing these three images of 1001, 1002, and 1003. However, a couple of methods in which a high dynamic range image is generated by compositing a plurality of images of which exposure properties are different have already been used in the industry, and the embodiment is not limited to a specific image compositing method.

In addition, when setting an exposure condition of each micro lens of the lens arrays 302 and 802, various methods are taken into consideration. As the method, there is a method of controlling transmissivity of light by arranging a filter on the front face of a lens, a method of determining an exposure amount by controlling a shutter speed, by arranging a mechanical shutter on the front face of a micro lens, though it is mechanically difficult, or the like. When a shutter speed is increased, it becomes a low exposure since a light intensity is reduced, and accordingly, it is possible to obtain an L component image. On the other hand, when the shutter speed is decreased, it becomes a high exposure since a light intensity is increased, and accordingly, it is possible to obtain an H component image.

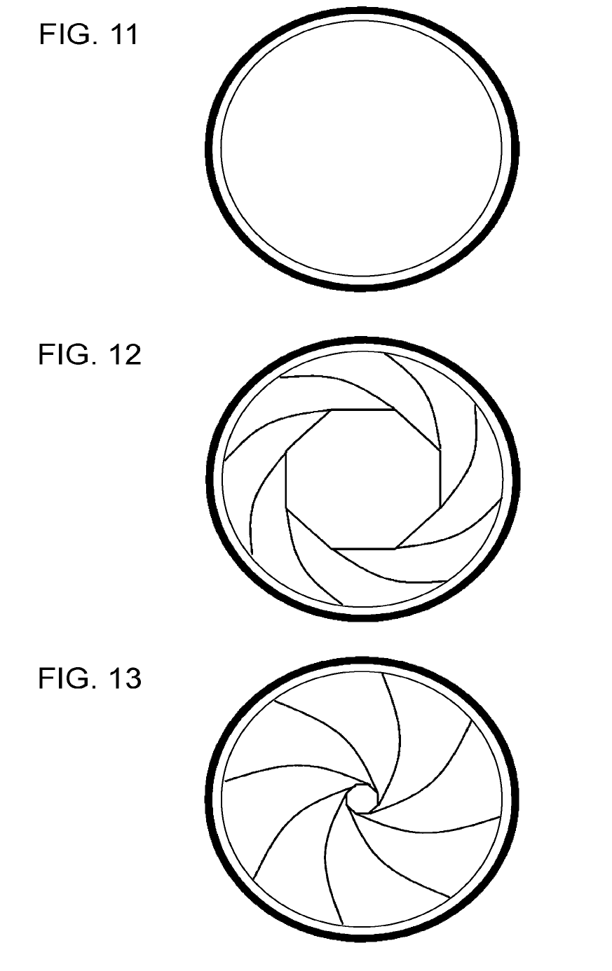

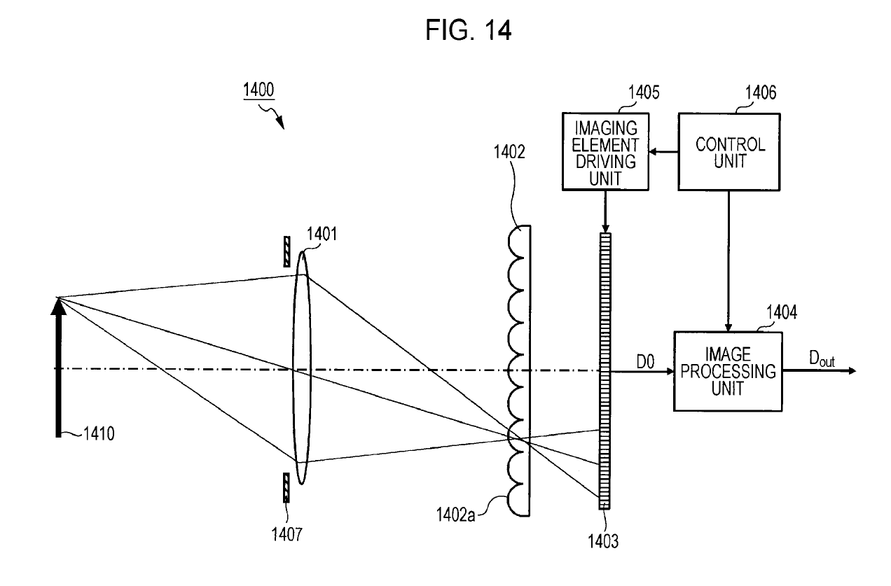

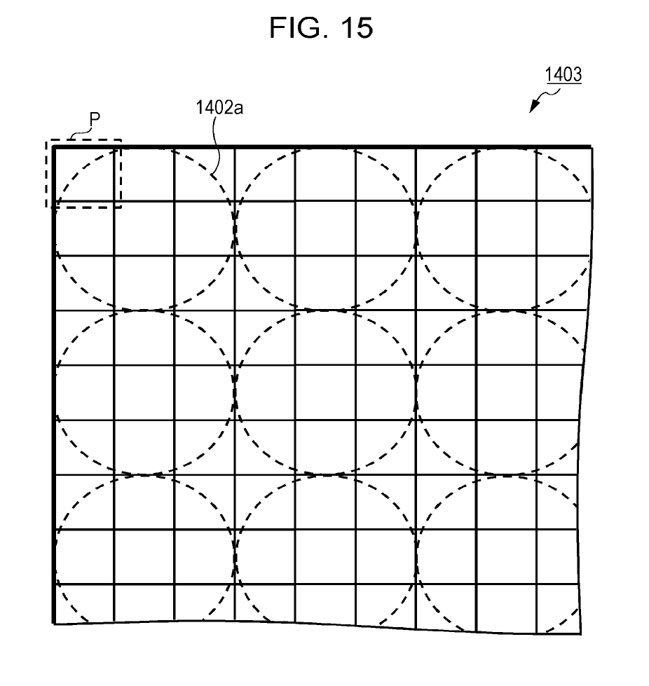

In addition, it is possible to set an exposure condition comparatively easily and effectively by arranging a diaphragm window at the outer periphery of each micro lens which configures the lens array 802 (or 302), and by respectively setting a narrowing amount corresponding to an exposure property of a corresponding pixel. FIG. 11 exemplifies a case in which a corresponding pixel is set to a high exposure amount by reducing a narrowing amount. In addition, FIG. 12 exemplifies a case in which a corresponding pixel is set to a medium exposure amount by setting a narrowing amount to a medium degree. In addition, FIG. 13 exemplifies a case in which a corresponding pixel is set to a low exposure amount by increasing a narrowing amount. These cases are the same as a diaphragm of a real single lens reflex camera in principle. It is possible to realize the diaphragm by attaching the illustrated diaphragm window to each micro lens by performing fine machining with respect to the diaphragm window.

As described above, in the imaging apparatus according to the embodiment, a lens array which is configured by arranging micro lenses on a two-dimensional plane is arranged on the front face of the imaging element. Since each micro lens respectively corresponds to one pixel of the imaging element, and different exposure conditions are set, the imaging apparatus generates a plurality of imaged images of which exposure conditions are different at the same point of time, and is capable of compositing a high dynamic range image from these imaged images. In the related art, frames of a plurality of point of times are captured in advance, and are composited (for example, refer to Japanese Unexamined Patent Application Publication No. 2013-255201); however, in contrast to this, according to the embodiment, since a process is completed in one frame, it is possible to save a frame memory, and there is an effect of shortening a delay time.

### Second Embodiment

FIG. 14 illustrates the entire configuration of an imaging apparatus 1400 according to a second embodiment of the technology which is disclosed in the specification. The illustrated imaging apparatus 1400 is configured by adopting the LFP technology, and includes an imaging lens 1401, a lens array 1402, an imaging element 1403, an image processing unit 1404, an imaging element driving unit 1405, and a control unit 1406. The imaging apparatus 1400 outputs image data Dₒᵤₜ by photographing an object 1410, and performing a predetermined image process.

The imaging lens 1401 is a main lens for imaging the object 1410, and for example, is configured of a general optical lens which is used in a video camera, or a still camera. An opening diaphragm 1407 is arranged on the light input side or the light output side (light input side in illustrated example) of the imaging lens 1401. An image of the object 1410 which is similar to a shape of an opening of the opening diaphragm 1407 (for example, circular shape) is formed in each image forming region of each micro lens of the lens array 1402 on the imaging element 1403.

The lens array 1402 is configured by arranging a plurality of micro lenses on a two-dimensional plane such as a glass substrate, or the like, for example. The lens array 1402 is arranged on a focal face (image forming face) of the imaging lens 1401, and the imaging element 1403 is arranged at a focal position of the micro lens of the lens array 1402. Each micro lens is configured of an individual lens, a liquid crystal lens, a diffraction lens, or the like, for example. Though it will be described later in detail, a two-dimensional arrangement of the micro lens in the lens array 1402 corresponds to a pixel array in the imaging element 1403.

The imaging element 1403 performs photoelectric conversion with respect to a ray which is received through the lens array 1402, and outputs imaged data DO. The imaging element 1403 is configured using a charge coupled device (CCD), or a complementary metal oxide semiconductor (CMOS), and has a structure in which a plurality of pixels are arranged in a matrix.

The rays which have passed through each micro lens of the lens array 1402 are respectively received in pixel blocks of m×n (for example, 2×2) of the imaging element 1403. That is, pixel blocks of m×n are allocated to one micro lens. In other words, it is possible to perform separating viewpoints of the number of pixels which are allocated to each micro lens (=the number of total pixels of imaging element 1403/the number of lenses of lens array 1402) using the lens array 1402.

The separating of viewpoints here means that a position (region) of the imaging lens 1401 which the ray which has passed through the imaging lens 1401 passes is stored in a unit of pixel of the imaging element 1403, by including directivity thereof. FIG. 15 illustrates an example of arranging the lens array 1402 and the imaging element 1403. In the illustrated example, 3×3 pixels on the imaging element 1403 are allocated to one micro lens 1402a, and a ray which has passed through the one micro lens 1402a is received in the 3×3 pixels. Accordingly, separating into 9 viewpoints in total is performed.

When the number of viewpoints which are separated increases, angular resolution in a parallax image increases; however, on the other hand, two-dimensional resolution in the parallax image increases when the number of pixels which is allocated to one micro lens decreases. That is, the angular resolution and the two-dimensional resolution of the parallax image are in a trade-off relationship. In the example illustrated in FIG. 15, separating into a total of 9 viewpoints is possible; however, resolution decreases to one ninth with respect to the original input image.

The image processing unit 1404 performs a predetermined image process with respect to the imaging data DO which is obtained in the imaging element 1403, and outputs a parallax image or a high dynamic range image in the embodiment as output image data Dₒᵤₜ. A detail of an image process for generating a parallax image or a high dynamic range image will be described later.

The imaging element driving unit 1405 drives the imaging element 1403, and performs a control of a light receiving operation thereof.

The control unit 1406 is configured of a micro computer, or the like, for example, and controls operations of the image processing unit 1404 and the imaging element driving unit 1405.

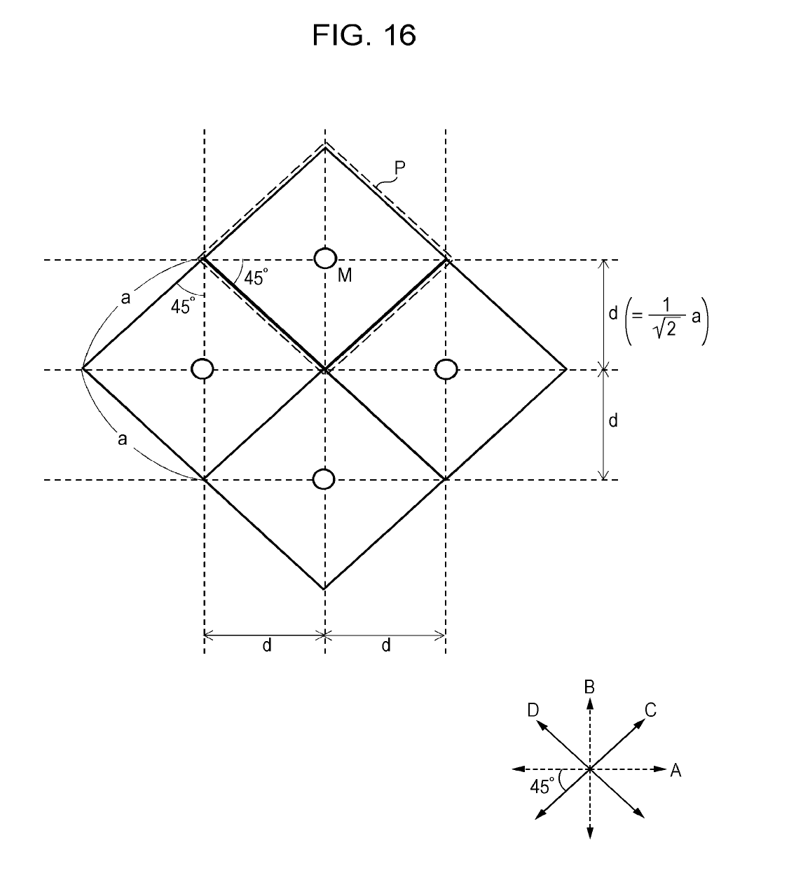

Subsequently, a pixel array in the imaging element 1403 will be described. FIG. 16 illustrates an example of the pixel array of the imaging element 1403 in the embodiment. However, in order to simplify the drawing, only pixels of 2×2 which are allocated to one micro lens are extracted and illustrated.

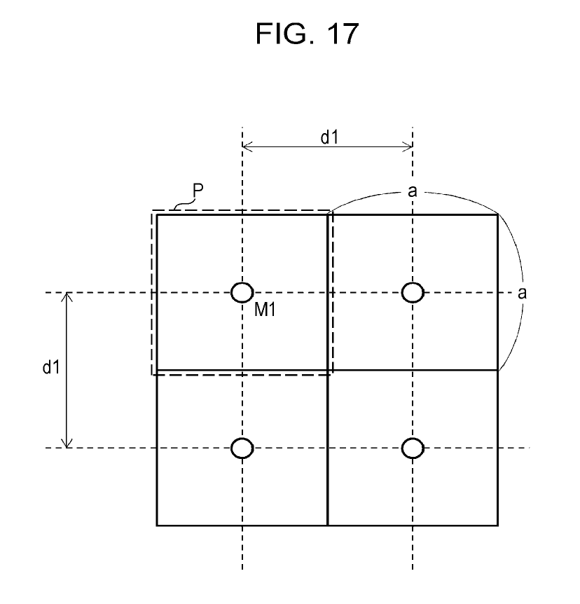

In the example illustrated in FIG. 16, the imaging element 1403 has a structure in which a square-shaped pixel P of which the length on one side is a is two-dimensionally arranged (hereinafter, simply referred to as “diagonal array”) in two directions which are diagonal with respect to the horizontal direction A and the vertical direction B, respectively, for example, along two directions of C and D which form 45° in the light receiving face. In FIG. 17, a common example of a pixel array (hereinafter, simply referred to as “square array”) in which a plurality of pixels P are arranged in a matrix along the horizontal direction A and the vertical direction B is illustrated as a comparison example. However, in order to simplify the drawing, only pixels of 2×2 which are allocated to one micro lens are extracted and illustrated.

In other words, in the diagonal array which is illustrated in FIG. 16, the plurality of pixels P arranged in a square shape which are illustrated in FIG. 17 are arranged in a state of being rotated by a predetermined angle (45°, in this case) in the light receiving face. In addition, a planar construction in which the micro lenses are two-dimensionally arranged along the two directions which are rotated by a predetermined angle (45°, in this case) with respect to the horizontal direction A and the vertical direction B is also set with respect to the lens array 1402, by corresponding to the diagonal array of the imaging element 1403 which is illustrated in FIG. 12. In addition, a color filter is arranged on the light receiving face side of the imaging element 1403; however, for a configuration example of a color arrangement of the color filter, for example, Japanese Unexamined Patent Application Publication No. 2010-154493 will be referred to.

In the square array which is illustrated in FIG. 17, since the square-shaped pixel P of which the length a of one side is two-dimensionally arranged along the horizontal direction A and the vertical direction B, a pitch d1 of the pixel P is the same as the length a of one side of the pixel P (that is, d1=a). However, the pitch d1 is a distance between centers M1 of neighboring pixels in the horizontal direction A and the vertical direction B.

On the other hand, in the diagonal array illustrated in FIG. 16, a pixel size itself of the pixel P is the same (that is, length of one side is a); however, the pitch d of the pixel P based on the horizontal direction A and the vertical direction B is reduced to 1/√2 times of the pitch d1 in a case of the square array. Due to this, the pixel pitch in the horizontal direction A and the vertical direction B is reduced (d<d1). However, the pitch d is set to a distance between centers M1 of neighboring pixels in the horizontal direction A and the vertical direction B.

In brief, in the configuration examples of the imaging apparatus 1400 which are illustrated in FIGS. 14 and 16, since the lens array 1402 to which pixels of 2×2 are allocated in each micro lens is arranged between the imaging lens 1401 and the imaging element 1403, it is possible to receive rays of the object 1410 as ray vectors of which viewpoints are different from each other. In addition, it is possible to make the pixel pitch in the horizontal direction A and the vertical direction B small compared to the case in which pixels with the same size are arranged in a square shape, that is, arranged two-dimensionally along the horizontal direction A and the vertical direction 8, by arranging the pixel P in the imaging element 1403 using the diagonal array which is illustrated in FIG. 16. In general, resolution of an image is easily recognized by human eyes in the horizontal and vertical directions, rather than the diagonal direction. Accordingly, it is possible to improve the number of superficial pixels (two-dimensional resolution) compared to the square array by adopting the diagonal array. That is, it is possible to obtain suggested information while suppressing deterioration in superficial resolution.

According to the imaging apparatus 1400 in the embodiment, in each micro lens of the lens array 1402, it is possible to receive rays of the object 1410 as ray vectors of which viewpoints are different from each other, from a principle of the LFP technology. Accordingly, it is possible to use an obtained parallax image as a stereoscopic image with binocular parallax, for example. When photographing a common stereoscopic image, a parallax image with binocular parallax is obtained using two cameras of a camera for a right eye, and a camera for a left eye. In contrast to this, in the imaging apparatus 1400 according to the embodiment, it is possible to easily obtain a stereoscopic image using one camera due to the principle of the LFP technology, and due to a generation of a parallax image using the micro lens. In addition, as described above, resolution rarely decreases in each parallax image.

Subsequently, a specific method of reading and generating image data when generating a parallax image in the imaging apparatus 1400 will be described.

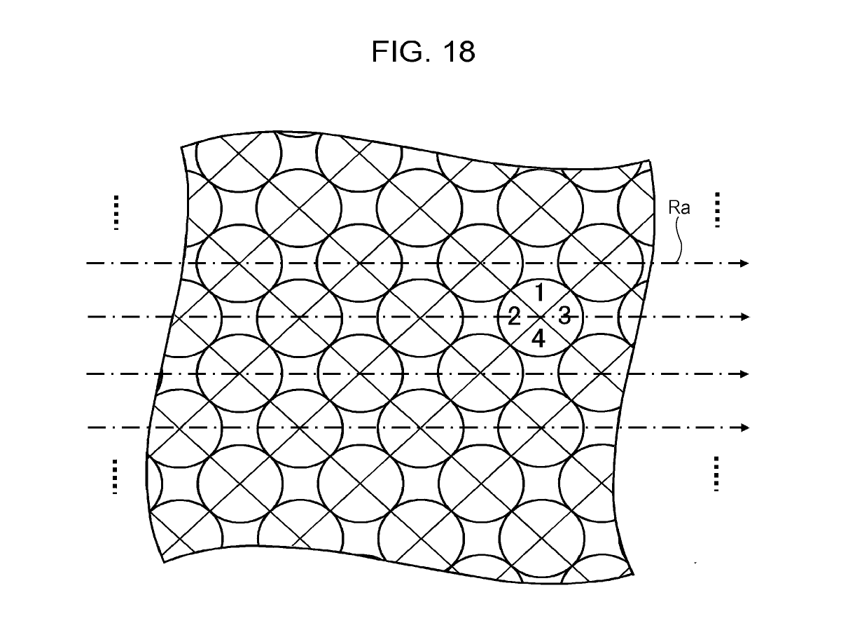

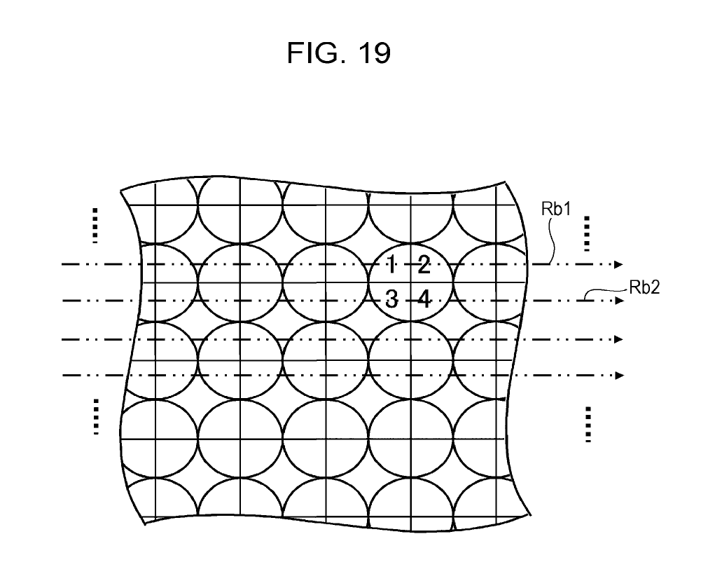

FIG. 18 illustrates a state in which image data of a parallax image is read from a pixel group which is diagonally arranged. In addition, in FIG. 19, a state in which image data of a parallax image is read from a pixel group which is arranged in a square shape is illustrated as a comparison. However, in each figure, each pixel of 2×2 which is allocated to one focused micro lens is denoted using numbers of 1 to 4, for convenience.

In the square array which is illustrated in FIG. 19, in order to obtain left and right parallax images which are targets of an optical axis, parallax images are generated by integrating pixels which are vertically neighboring, that is, pixels 1 and 3, and 2 and 4 in FIG. 19. For this reason, it is necessary to read image data from all of four pixels 1 to 4 which are allocated to the same micro lens. In this case, two read lines Ra and Rb are necessary in each micro lens.

In contrast to this, in the diagonal array which is illustrated in FIG. 18, it is possible to generate left and right parallax images which are targets of the optical axis, by reading image data of the pixel 2 and pixel 3 in each micro lens. Since the pixel 2 and the pixel 3 from which image data is read are arranged on the same line, reading may be performed in one reading line Ra, and accordingly, it is possible to read image data at a high speed compared to the square array. In addition, in a case of the diagonal array, it is possible to obtain a parallax image of an object with deep depth of field, since an integration process is not necessary. In addition, in FIG. 18, the left and right parallax images are described as examples; however, the same is applied to a case in which two vertical parallax images are generated. In this case, image data of the pixel 1 and the pixel 4 may be read in one reading line in each micro lens.

However, in the case of the diagonal array which is illustrated in FIG. 18, when left and right parallax images are generated by reading image data from the pixel 2 and the pixel 3, there is a problem in that image data of the pixel 4 in a direction in which the higher pixel is set to 1 becomes useless without being used. Similarly, also in a case in which vertical parallax images are generated by reading image data from the pixel 1 and the pixel 4, the pixel 2 on the left, and the pixel 3 on the right remain unused.

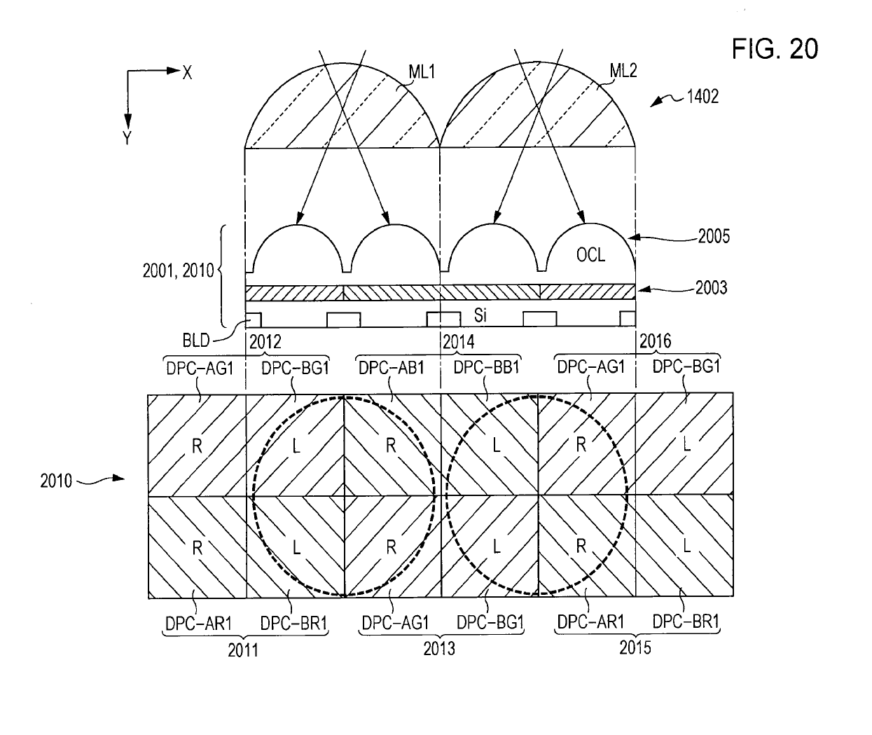

In order to solve the problem that part of image data remains unused, and becomes useless, adopting a configuration of an imaging element in which each micro lens performs separating of left and right parallax by allocating a right half of a left pixel and a left half of a right pixel in two pixels which are neighboring in the horizontal direction to one micro lens, as illustrated in FIG. 20, instead of the configuration in which a plurality of (m×n) pixels are allocated to one micro lens, as illustrated in FIG. 14 or 16, is taken into consideration.

In FIG. 20, one micro lens M1 of the lens array 1402 forms a left eye image on the right half of the left pixel, and forms a right eye image on the left half of the right pixel in two corresponding pixels which are neighboring in the horizontal direction, when receiving rays of the object 1410 as respective ray vectors of a left eye viewpoint and a right eye viewpoint. Since left eye image data is read from the left half, and right eye image data is read from the right half in each pixel, there is no image data which remains unused, and there is no waste. In the configuration illustrated in FIG. 20 in which separating of left and right parallax is performed in the micro lens, horizontal resolution becomes a half; however, the configuration is useful since the configuration matches a side-by-side (SBS) recording method. In FIG. 20, L denotes a left side in a stereoscopic image, and R denotes a right side in a stereoscopic image. There also is a case in which L and R are reversed due to optical properties, and in such a case, it is possible to correspond thereto by switching L and R. In the configuration illustrated in FIG. 20, a color filter array is formed so as to form a 2×2 array.

In addition, in FIG. 20, a configuration example in which pixels of the imaging element 1403 are arranged in a square shape is illustrated in order to facilitate understand. The configuration in which pixels are diagonally arranged will be described later. In addition, when it is desired to have a configuration in which a micro lens performs separating of vertical parallax, not of horizontal parallax, though it is not illustrated, a lower half of a higher pixel and a higher half of a lower pixel may be allocated to one micro lens in two pixels which are neighboring in the vertical direction.

In the imaging element illustrated in FIG. 20, a color filter array with a square array and a Bayer array is arranged in a pixel array unit 2010. A color filter array 2003 is formed so that an R pixel (PCR) 2011, a G pixel (PCG) 2012, a G pixel (PCG) 2013, a B pixel (PCB) 2014, an R pixel (PCR) 2015, a G pixel (PCG) 2016, . . . form a Bayer array of 2×2. The G pixel (PCG) 2012, the B pixel (PCB) 2014, the G pixel (PCG) 2016, . . . are arranged on the first row, and the R pixel (PCR) 2011, the G pixel (PCG) 2013, the R pixel (PCR) 2015, . . . are arranged on the second row. Only a part of the pixel array unit 2010 is illustrated in FIG. 20; however, also in portions which are not illustrated, neighboring G pixels with the Bayer array are arranged in the horizontal direction (X direction) of the B pixel, and neighboring R pixels with the Bayer array are arranged in the horizontal direction (X direction) of the G pixel.

In addition, in the example illustrated in FIG. 20, the R pixel (PCR) 2011, the G pixel (PCG) 2012, the G pixel (PCG) 2013, the B pixel (PCB) 2014, the R pixel (PCR) 2015, the G pixel (PCG) 2016, . . . are respectively divided into two in the horizontal direction (X direction).

The R pixel (PCR) 2011 is configured by including two division pixels of pixels DPC-AR1 and DPC-BR1. In addition, the division pixel DPC-AR1 is allocated to an image for R of a stereoscopic image, and the division pixel DPC-BR1 is allocated to an image for L of the stereoscopic image. The same is applied to the R pixel (PCR) 2015.

The G pixel (PCG) 2012 is configured by including two division pixels of pixels DPC-AG1 and DPC-BG1. In addition, the division pixel DPC-AG1 is allocated to an image for R of a stereoscopic image, and the division pixel DPC-BG1 is allocated to an image for L of the stereoscopic image. The same is applied to the G pixel (PCG) 2013 and the G pixel (PCG) 2016.

In addition, the B pixel (PCB) 2014 is configured by including two division pixels of pixels DPC-AB1 and DPC-BB1. In addition, the division pixel DPC-AB1 is allocated to an R image of a stereoscopic image, and the division pixel DPC-BB1 is allocated to an L image of the stereoscopic image.

In the pixel array which is illustrated in FIG. 20, each division pixel on the same column (array in Y direction) is allocated to an image for R or an image for L of the same stereoscopic image.

On a semiconductor substrate 2001, a light shielding unit (BLD) or wiring is formed, the color filter array 2003 is formed on a higher layer thereof, and an on-chip lens array 2005 is formed on a higher layer of the color filter array 2003. Each on-chip lens (OCL) of the on-chip lens array 2005 is formed in a matrix so as to correspond to each division pixel in the pixel array unit 2010. In addition, the lens array 1402 in which micro lenses are two-dimensionally arranged is arranged by facing a light input side of the on-chip lens array 2005.

In the example which is illustrated in FIG. 20, it is configured such that each micro lens performs separating of left and right parallax by allocating a right half of a left pixel and a left half of a right pixel in two pixels which are neighboring in the horizontal direction to one micro lens (ML). In addition, the color filter array 2003 is arranged so that pixels which share the same micro lens have different colors, not the same color.

For example, the first micro lens ML1 is arranged so as to be shared by the division pixel DPC-BG1 for L of the stereoscopic image of the G pixel (PCG) 2012, and the neighboring division pixel DPC-AB1 for R of the stereoscopic image of the B pixel (PCB) 2014 in the first row. Similarly, the first micro lens ML1 is arranged so as to be shared by the division pixel DPC-BR1 for L of the stereoscopic image of the R pixel (PCR) 2011, and the neighboring division pixel DPC-AG1 for R of the stereoscopic image of the G pixel (PCG) 2013 in the second row.

In addition, the second micro lens ML2 is arranged so as to be shared by the division pixel DPC-BB1 for L of the stereoscopic image of the B pixel (PCB) 2014, and the neighboring division pixel DPC-AG1 for R of the stereoscopic image of the G pixel (PCG) 2016 in the first row. Similarly, the second micro lens ML2 is arranged so as to be shared by the division pixel DPC-BG1 for an L image of the stereoscopic image of the G pixel (PCG) 2013, and the neighboring division pixel DPC-AR1 for R of the stereoscopic image of the R pixel (PCR) 2015 in the second row.

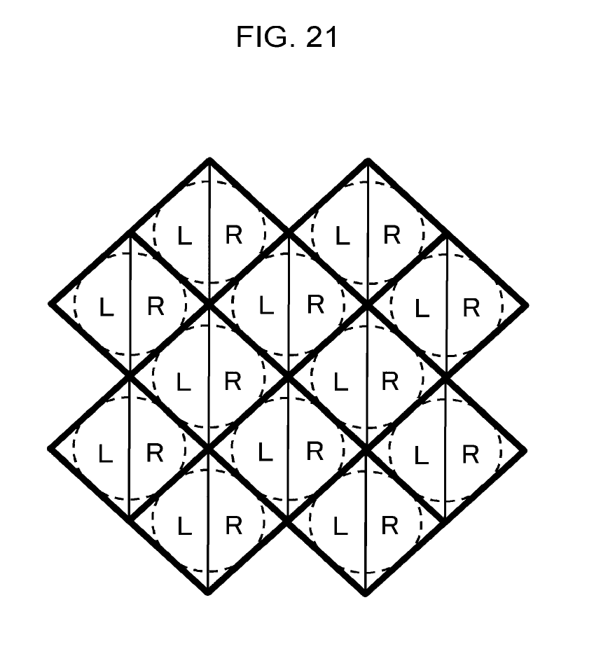

In FIG. 20, a configuration example in which pixels of the imaging element 1403 are arranged in a square shape is illustrated. In contrast to this, in FIG. 21, a structure of the imaging element 1403 in which square-shaped pixels are diagonally arranged in two diagonal directions with respect to the respective horizontal direction (X direction) and vertical direction (Y direction), for example, in two directions which form 45°, is illustrated. In addition, in order to simplify the drawing, an arrangement of the color filter array is omitted.

Each pixel which is diagonally arranged is divided into two in the horizontal direction (X direction). In addition, a left division pixel of each pixel is allocated to an L image of a stereoscopic image, and a right division pixel is allocated to an R image of the stereoscopic image, respectively. In addition, in the pixel array illustrated in FIG. 21, each division pixel on the same column (array in Y direction) is allocated to an R image or an L image of the same stereoscopic image. That is, it is possible to detect two parallaxes on the left and right by dividing a pixel which is diagonally arranged into two.

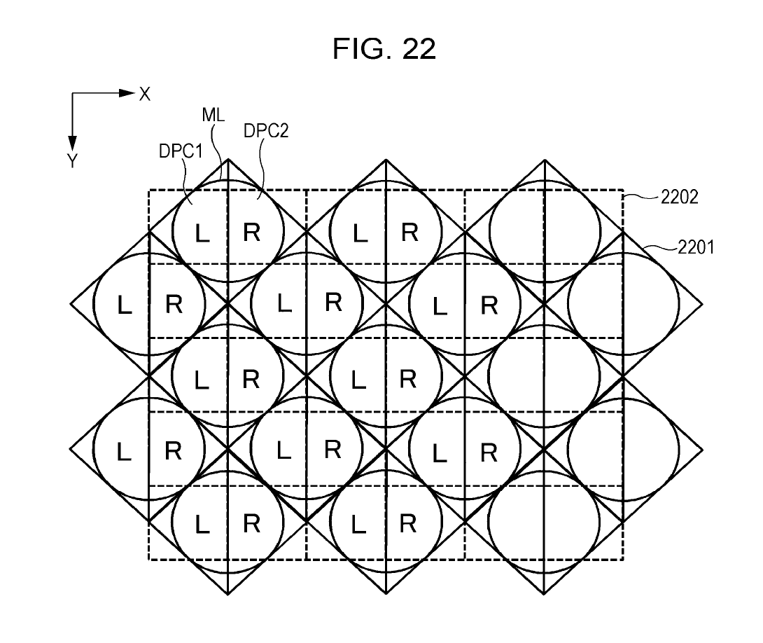

Each unit pixel of the imaging element with the diagonal array which is illustrated in FIG. 21 is configured so that a first pixel unit 2201 which has at least a light receiving function (including micro lens and on-chip lens), and a second pixel unit 2202 which is formed so as to face the first pixel unit, and has at least a detection function are stacked, as illustrated in FIG. 22, for example. The first pixel unit 2201 is formed using a diagonal array, and the second pixel unit 2202 is formed using a square array. A row array and a column array of the first pixel unit 2201, and a row array and a column array of the second pixel unit 2202 are formed so as to correspond to each other. For example, the first pixel unit 2201 includes an on-chip lens, and the second pixel unit 2202 includes a wiring layer and a photodiode along with a detection element. Alternatively, it may be a configuration in which the first pixel unit 2201 includes a color filter along with the on-chip lens, and the second pixel unit 2202 includes the wiring layer and the photodiode along with the detection element. Alternatively, it may also be a configuration in which the first pixel unit 2201 includes the color filter, and the photodiode along with the on-chip lens, and the second pixel unit 2202 includes the wiring layer along with the detection element.

Each pixel of the first pixel unit 2201 which is diagonally arranged is formed in a state of being rotated by 45° in the Y direction toward the X direction, for example, so as to straddle two neighboring columns of a row corresponding to the second pixel unit 2202 which is arranged in a square shape. In addition, each pixel of the first pixel unit 2201 is configured so as to include division pixels of DPC1 and DPC2 in a triangular shape which are horizontally divided into two about a Y axis, and in which each division pixel DPC1 is arranged on the left column of neighboring two columns of the second pixel unit 2202, and the DPC2 is arranged on the right column. In addition, one micro lens (ML) is arranged so as to be shared by the two division pixels of DPC1 and DPC2 with the same color in a straddling manner. In addition, one division pixel DPC1 is allocated to an L image of a stereoscopic image, and the other division pixel DPC2 is allocated to an R image of the stereoscopic image. Image data with the same color of each division pixel DPC1 and DPC2 for the R image and the L image which are included in each pixel of the first pixel unit 2201 can be read from pixels of neighboring two columns on the second pixel unit 2202 side, and the mechanism is the same as that in the imaging element which is illustrated in FIG. 20.

In a case of the imaging element with the diagonal array which is illustrated in FIG. 21, it is possible to generate a left and right parallax image which is an optical axis target, by reading image data of a division pixel for L of a stereoscopic image, and image data of a division pixel for R of the stereoscopic image, in each micro lens. In addition, since the division pixels for R and L images for reading image data are arranged on the same line, the reading may be performed in one reading line, and accordingly, it is possible to read image data at high speed compared to the square array. In addition, in a case of the diagonal array, it is possible to obtain a parallax image of an object with deep depth of field, since the integration process is not necessary. In addition, when a left and right parallax image is generated by reading image data from division pixels for R and L images, there is no image data which remains unused. That is, there is no useless pixel array, and it is possible to suppress deterioration in resolution due to stereopsis.

The configuration example of the imaging element (pixel array unit) which is illustrated in FIG. 21 has a structure in which one pixel is allocated to one micro lens, and each pixel is horizontally divided into two, and in which it is possible to efficiently obtain a parallax image with binocular parallax. When adopting a structure in which a plurality of pixels are allocated to one micro lens, and each pixel is horizontally divided into two as a modification example of this, it is possible to efficiently obtain a parallax image which includes a multiple viewpoint image.

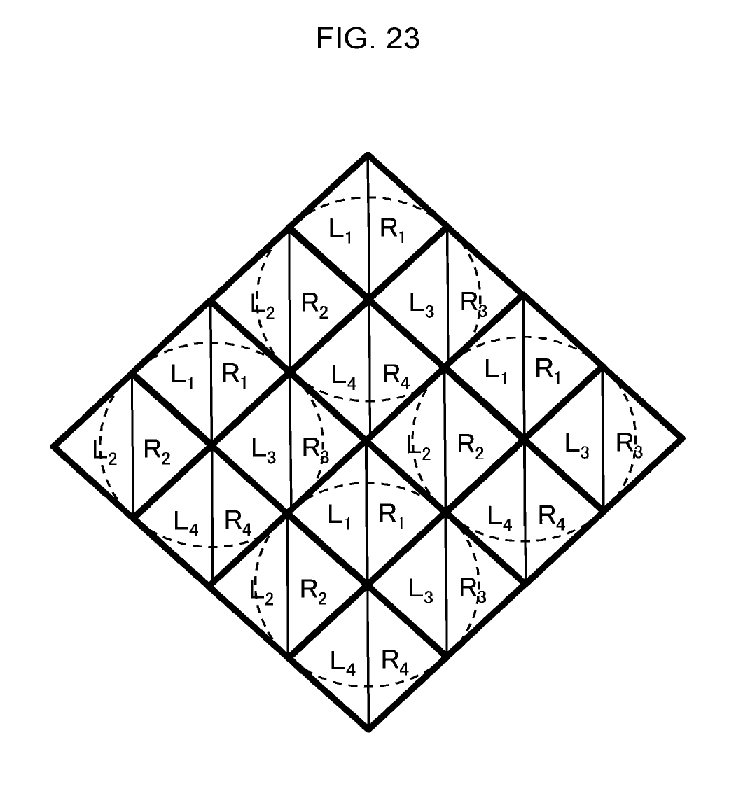

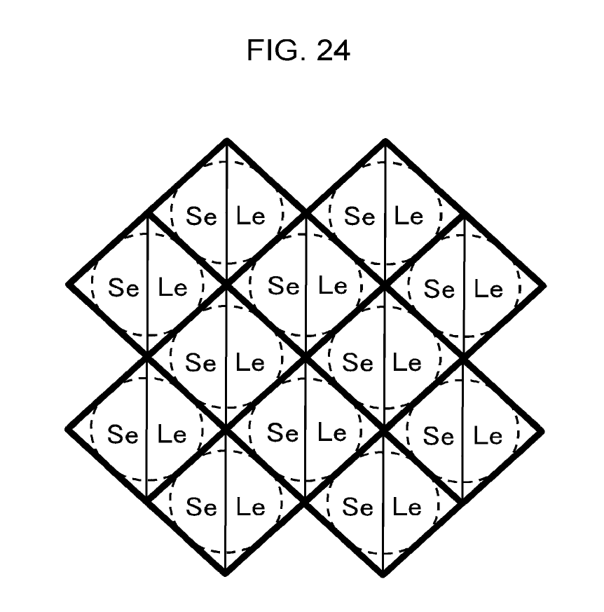

FIG. 23 illustrates a state in which 2×2 pixels are allocated to one micro lens in a pixel array in which pixels are diagonally arranged at an inclination of 45°. In addition, in order to simplify the drawing, an array of a color filter is omitted.

Though it is not illustrated, also in the imaging element which is illustrated in FIG. 23, each unit pixel is configured so that a first pixel unit which has at least a light receiving function (including micro lens and on-chip lens), and a second pixel unit which is formed so as to face the first pixel unit, and has at least a detection function are stacked. The first pixel unit is formed using a diagonal array, and the second pixel unit is formed using a square array.

A row array and a column array of the first pixel unit, and a row array and a column array of the second pixel unit are formed so as to correspond to each other. Each pixel of the first pixel unit which is diagonally arranged is formed in a state of being rotated by 45° in the Y direction toward the X direction, for example, so as to straddle two neighboring columns of a row corresponding to the second pixel unit which is arranged in a square shape. In addition, each pixel of the first pixel unit is configured so as to include division pixels which have triangular shapes which are horizontally divided into two about the Y axis, and in which each division pixel is arranged in respective left and right columns of neighboring two columns of the second pixel unit. In addition, one micro lens (ML) is arranged so as to be shared by 2×2 pixels with the same color in a straddling manner. Image data of each division pixel which is included in each pixel of the first pixel unit is read from pixels of neighboring two columns on the second pixel unit side, and the mechanism is the same as that in the imaging element which is illustrated in FIG. 20.

In the configuration example of the imaging element (pixel array unit) which is illustrated in FIG. 23, in 2×2 pixels which are allocated to one micro lens, half of each division pixel on the left side about the Y axis is allocated to an L image of a stereoscopic image, and half of each division pixel on the right side is allocated to an R image of the stereoscopic image. However, FIG. 23 is an example of a stereoscopic image when imaging elements are diagonally arranged, and there are many configuration examples other than that.

In FIG. 23, all of image data items which are read from the left half of 2×2 pixels which are diagonally arranged at an inclination of 45° are integrated, and all of image data items which are read from the right half, thereby obtaining a left and right parallax image. In addition, it is also possible to obtain a multiple parallax image of three or more parallaxes by combining image data which is read from arbitrary two or more division pixels for L, and image data which is read from arbitrary two or more division pixels for R, and by processing thereof.

In FIG. 23, a method of processing (compositing) image data items which are read from each division pixel is arbitrary. It is possible to generate eight parallax images of (L₁, R₁), (L₂, R₂), (L₃, R₃), and (L₄, R₄) at maximum. In addition, it is possible to generate four parallax images by combining division pixels of two sets such as (L₁, R₁) and (L₂, R₂), and (L₃, R₃) and (L₄, R₄). As a matter of course, it is not necessary to use image data of all of division pixels, and it is also possible to take into consideration an image processing method in which image data of a part of division pixels is caused to remain unused.

According to the configuration example of the imaging element (pixel array unit) which is illustrated in FIG. 23, it is possible to obtain more parallax images than in the configuration example which is illustrated in FIG. 21. On the other hand, great attention should be paid to deterioration in resolution.

### Third Embodiment

Hitherto, the method of generating a stereoscopic image using binocular parallax of left and right in the imaging apparatus 1400 to which the LFP technology is applied has been described. It is also possible to generate a high dynamic range (HDR) image using the same imaging element 1400 to which the LFP technology is applied. Hereinafter, an embodiment in which an HDR image is generated using the imaging apparatus 1400 to which the LFP technology is applied will be described.

In FIG. 21, a structure of the imaging element 1403 in which square-shaped pixels are diagonally arranged in two directions which are diagonal to the horizontal direction (X direction) and vertical direction (Y direction), respectively, for example, along two directions which form 45°, is illustrated. Each pixel which is diagonally arranged includes a division pixel in a triangular shape which is divided into two in the horizontal direction (X direction) about the Y axis, that is, on the left and right, and in the second embodiment, a binocular parallax image is obtained by allocating a division pixel of each pixel on the left side to an L image of a stereoscopic image, and allocating a division pixel of each pixel on the right side to an R image of the stereoscopic image, respectively.

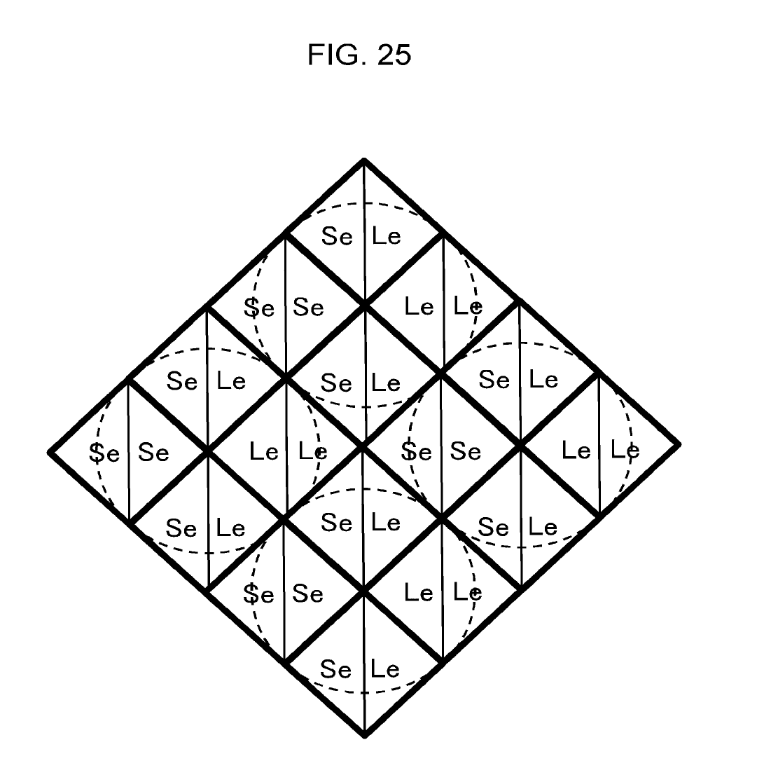

In contrast to this, according to the embodiment, as illustrated in FIG. 24, short exposure (Se) is performed instead of reading image data for L of a stereoscopic image from a division pixel of each pixel on the left side, and long exposure (Le) is performed instead of reading image data for R of the stereoscopic image from a division pixel on the right side. As described in advance, a couple of methods for generating an HDR image by compositing a plurality of images of which exposure properties are different are used in the industry. According to the embodiment, it is possible to generate an HDR image by compositing image data which is obtained from each of the division pixel which is exposed with a low exposure amount using short exposure (Se), or the like, and the division pixel which is exposed with a high exposure amount using long exposure (Le), or the like, in a unit of micro lenses.

In addition, FIG. 23 illustrates a structure of the imaging element 1403 in which 2×2 pixels are allocated to one micro lens in a pixel array in which pixels are diagonally arranged. Each pixel which is diagonally arranged includes a division pixel in a triangular shape which is divided into two in the horizontal direction (X direction), that is, on the left and right, respectively. According to the second embodiment, it is possible to obtain a binocular parallax image by allocating half of each division pixel on the left side about the Y axis in the figure to an L image of a stereoscopic image, and allocating half of each division pixel on the right side to an R image of the stereoscopic image among 2×2 pixels which are allocated to one micro lens.

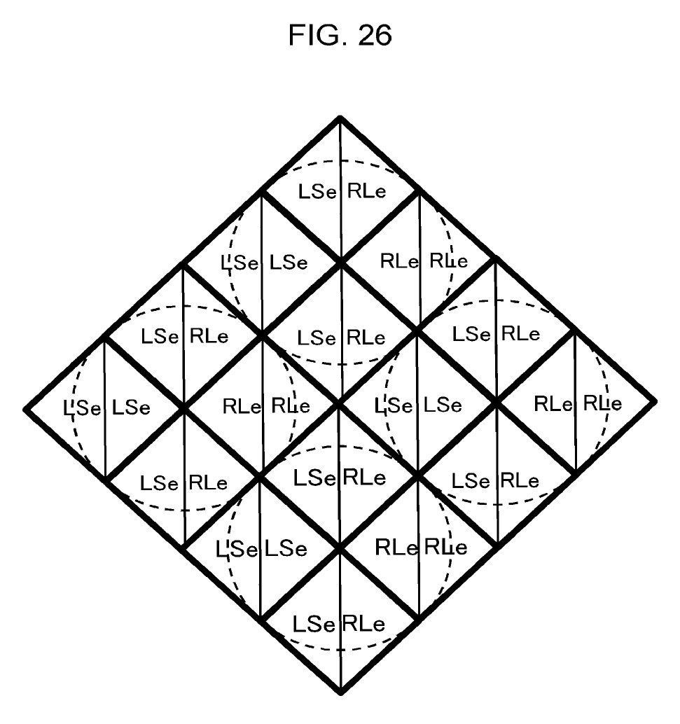

In contrast to this, according to the embodiment, as illustrated in FIG. 25, short exposure (Se) is performed in a corresponding pixel of the second pixel unit instead of reading image data for L of a stereoscopic image from half of each division pixel on the left side about the Y axis of each of 2×2 pixels, and long exposure (Le) is performed in a corresponding pixel of the second pixel unit, instead of reading image data for R of the stereoscopic image from half of each division pixel on the right side about the Y axis. As described in advance, a couple of methods for generating an HDR image by compositing a plurality of images of which exposure properties are different are used in the industry. According to the embodiment, it is possible to generate an HDR image by compositing image data which is obtained from each of the pixel which is exposed with a low exposure amount using short exposure (Se), or the like, and the pixel which is exposed with a high exposure amount using long exposure (Le), or the like, in a unit of micro lens.

In addition, through it is not illustrated in FIGS. 24 and 25, an HDR image may be generated by further receiving a division pixel in which middle exposure is performed using middle exposure (Me), in addition to the short exposure (Se) and the long exposure (Le), obtaining image data of middle exposure, and compositing three types of image data of which exposure properties are different in a unit of micro lens.

In addition, a method of performing adjusting of a narrowing amount as illustrated in FIGS. 11 to 13 in each on-chip lens is also taken into consideration, in addition to a method of setting different exposure times in each division pixel, in order to obtain image data with a plurality of types of different exposure properties.

In addition, by performing separating of left and right parallax using a micro lens, and setting of a plurality of exposure properties using an exposure time, or the like, at the same time in the imaging apparatus 1400 to which the LFP technology is applied, it is possible to generate stereoscopic images with characteristics of the high dynamic range (HDR) image at the same time.

FIG. 26 illustrates a mechanism in which a high dynamic range stereoscopic image is obtained from imaging elements which are diagonally arranged by applying the LFP technology. Each unit pixel of the imaging element is configured so that a first pixel unit which has at least a light receiving function (including micro lens and on-chip lens), and a second pixel unit which is formed so as to face the first pixel unit, and has at least a detection function, are stacked. In addition, the first pixel unit is formed using a diagonal array, and the second pixel unit is formed using a square array (the same as above).

A row array and a column array of the first pixel unit, and a row array and a column array of the second pixel unit are formed so as to correspond to each other. Each pixel of the first pixel unit which is diagonally arranged is formed in a state of being rotated by 45° in the Y direction toward the X direction, for example, so as to straddle two neighboring columns of a row corresponding to the second pixel unit which is arranged in a square shape. In addition, each pixel of the first pixel unit is configured so as to include a division pixel in a triangular shape which is horizontally divided into two about the Y axis, and each division pixel is arranged in the respective left and right columns of two neighboring columns of the second pixel unit. In addition, one micro lens (ML) is arranged so as to be shared by 2×2 pixels with the same color in a straddling manner. Image data of each division pixel which is included in each pixel of the first pixel unit is read from pixels of neighboring two columns on the second pixel unit side, and the mechanism is the same as that in the imaging element which is illustrated in FIG. 20.

In the configuration example of the imaging element (pixel array unit) which is illustrated in FIG. 26, in 2×2 pixels which are allocated to one micro lens, half of each division pixel on the left side about the Y axis is allocated to an L image of a stereoscopic image, and half of each division pixel on the right side is allocated to an Image for R of the stereoscopic image. However, FIG. 26 is an example of a stereoscopic image when imaging elements are diagonally arranged, and there are many configuration examples other than that.

In addition, in pixels of the second pixel unit corresponding to half of each division pixel on the left side about the Y axis in each of 2×2 pixels, short exposure (Se) respectively is performed. In addition, in pixels of the second pixel unit corresponding to half of each division pixel on the right side about the Y axis, long exposure (Le) is respectively performed.

In the example which is illustrated in FIG. 26, there are the following image data with four different conditions in each of 2×2 pixels, that is, in one micro lens.

LLe: Left+Long Exposure (long exposure in left image)
LSe: Left+Short Exposure (short exposure in left image)
RLe: Right+Long Exposure (long exposure in right image)
RSe: Right+Short Exposure (short exposure in right image)

As described in advance, a couple of methods for generating an HDR image by compositing a plurality of images of which exposure properties are different have been used in the industry. When image data items with the above described four conditions are present in one micro lens, it is possible to generate a high dynamic range image which is a left image by compositing image data of LLe and LSe. In addition, it is possible to generate a high dynamic range image which is a right image by compositing image data of RLe and Rse.

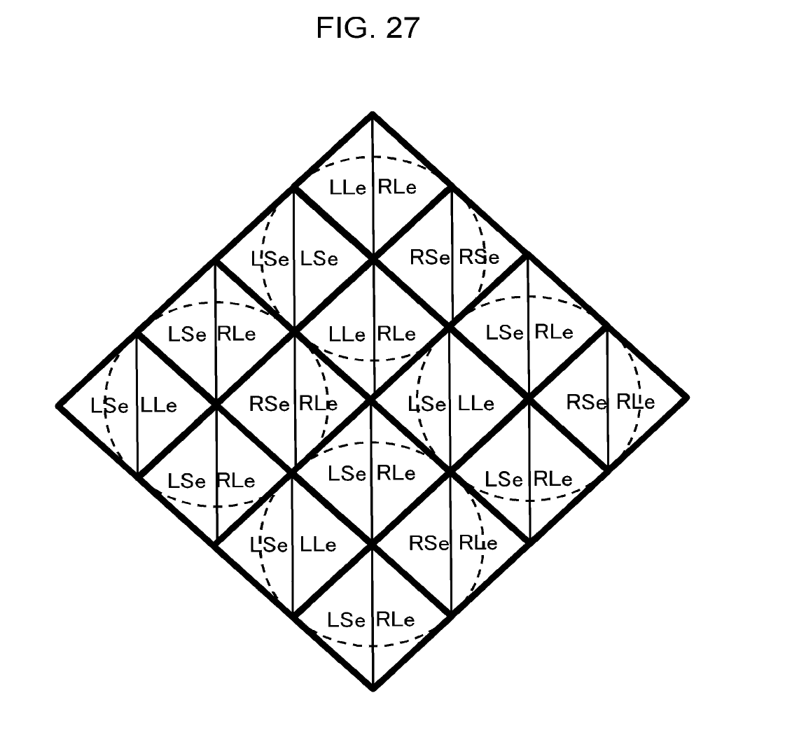

In addition, FIG. 26 is one configuration example for obtaining a high dynamic range parallax image, and the technology which is disclosed in the specification is not limited to this. FIG. 27 illustrates another configuration example for obtaining a high dynamic range parallax image. In any configuration, it is possible to generate a high dynamic range image which is a left image by compositing image data of LLe and LSe, and it is possible to generate a high dynamic range image which is a right image by compositing image data of RLe and Rse in one micro lens.

In addition, when setting exposure conditions of pixels, various methods are taken into consideration, in addition to the above described method in which an exposure time is controlled. There are a method in which transmissivity of light is controlled by providing a filter on the front face of a lens (including method of controlling transmissivity of light of lens its own), a method in which a mechanical shutter is provided on the front face of a lens (micro lens or on-chip lens), and determines an exposure amount by controlling a shutter speed, and the like. Since light intensity decreases when making a shutter speed fast, this state corresponds to the above described short exposure Se, and image data with a component of a low exposure amount is obtained. On the other hand, since light intensity increases when making a shutter speed slow, this state corresponds to the above described long exposure Le, and image data with a component of a high exposure amount is obtained.

In addition, the method of providing a diaphragm window, as illustrated in FIGS. 11 to 13, at the outer periphery of a lens (micro lens or on-chip lens) is relatively easy, and is highly effective. It is possible to attach the diaphragm window, for example, by performing micro-fabrication with respect to each lens, and it has the same principle as that of a diaphragm which is used in real single-lens reflex camera. When a diaphragm is open as illustrated in FIG. 11, since it enters a high exposure state, the state corresponds to the above described long exposure Le. On the other hand, when the diaphragm is closed as illustrated in FIG. 13, since it enters a low exposure state, the state corresponds to the above described short exposure Se.

### Fourth Embodiment

Hitherto, the method of generating a high dynamic range image or a parallax image using an imaging apparatus to which the LFP technology is applied has been described. Usually, an image has a great amount of information. Accordingly, in general, the amount of information is reduced using image compression. In particular, in a case of a moving image, image compression is important.

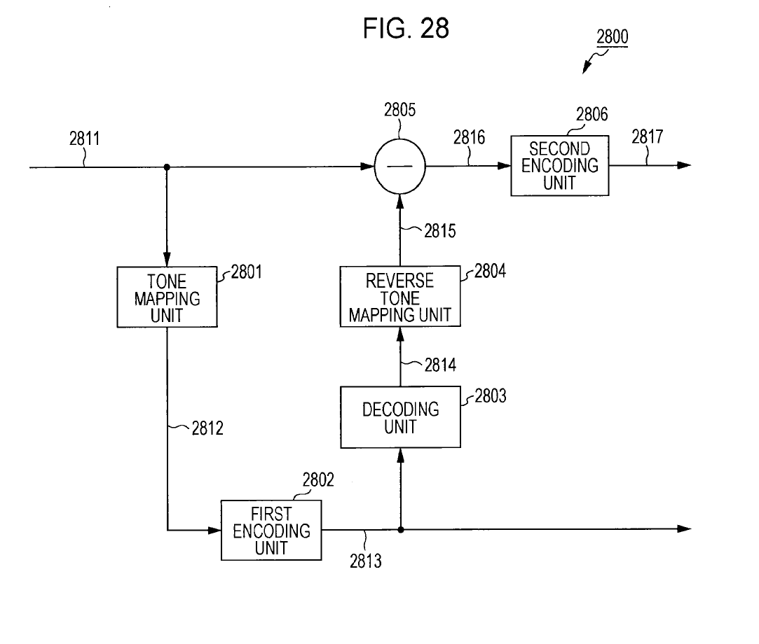

FIG. 28 illustrates a configuration example of an image compression device 2800 which compresses a high dynamic-range image. The illustrated image compression device 2800 is arranged at a rear part of an image processing unit 1404, for example, and performs a compression process with respect to non-compressed image data Dₒᵤₜ which is output from the image processing unit 1404 at a predetermined compression ratio. The illustrated image compression device 2800 includes a tone mapping unit 2801, a first encoding unit 2802, a decoding unit 2803, a reverse tone mapping unit 2804, a difference calculation unit 2805, and a second encoding unit 2806. The image compression device 2800 adopts an encoding method of a two-stage configuration in which an image with a low bit depth is created by performing tone mapping, and a difference between a decoded image thereof and the original image are further encoded using a separate encoder.

Data 2811 which is input to the image compression device 2800 is a high dynamic range image, and is assumed to be expressed in high bit depth of 8 or more bits, and of an accuracy of one decimal point. As a method of encoding a high bit depth image, a plurality of methods are suggested. For example, a process of converting bit depth using tone mapping is used in the industry. According to the embodiment, the tone mapping unit 2801 performs tone mapping with respect to the input high dynamic range image 2811, and converts the image into an image 2812 of 8 bits. Accordingly, in the subsequent first encoding unit 2802, an encoding process corresponding to an image of 8 bit depth such as a Joint Photographic Experts Group (JPEG) or a Moving Picture Experts Group (MPEG) is applied.

The decoding unit 2803 performs a decoding process corresponding to a reverse conversion of the encoding process using the first encoding unit 2802 with respect to a encoding result 2813 of the first encoding unit 2802, and obtains a decoded image 2814. When the encoding process using the first encoding unit 2802 and the decoding process using the decoding unit 2803 are reversible modes, the 8 bit image 2812 before encoding and the image 2814 after decoding completely match; however, usually, the two do not match (image 2814 after decoding becomes a deteriorated image compared to image 2812 before encoding) each other, since compression is not performed in order to improve a compression ratio.

The reverse tone mapping unit 2804 performs a reverse tone mapping process corresponding to a reverse conversion of the tone mapping process using the tone mapping unit 2801 with respect to the image 2814 after decoding using the decoding unit 2803.

As described above, since the encoding process in the first encoding unit 2802 is in a non-compressing mode, an image 2815 which is subjected to reverse tone mapping using the reverse tone mapping unit 2804 does not match the input image 2811. The difference calculation unit 2805 calculates a difference between the image 2815 which is subjected to reverse tone mapping using the reverse tone mapping unit 2804 and the input image 2811, and outputs a difference image 2816.

The second encoding unit 2806 performs an encoding process with respect to the difference image 2816, and outputs an encoding result 2817.

Accordingly, in the entire image compression device 2800, two results of the encoding result 2813 of the first encoding unit 2802 corresponding to a usual 8 bit depth image, for example, and the encoding result 2817 of a difference image (that is, with respect to error of encoding) between high dynamic range images, are output.

As such an advantage, for example, it is possible to provide a compressed image with respect to both the existing device which is capable of corresponding only to an 8 bit depth image and the device which is also capable of corresponding to a high dynamic range image (however, “device” here includes image viewer, or various software and hardware).

The image compression device 2800 may output only the encoding result 2813 using the first encoding unit 2802 with respect to the existing device which is capable of corresponding only to the 8 bit depth image. In addition, the image compression device 2800 may output two results of the encoding result 2813 using the first encoding unit 2802, and the encoding result 2817 of a differential image using the second encoding unit 2806 with respect to the device which is also capable of corresponding to the high dynamic range. That is, it can be said that the image compression device 2800 has backward compatibility with respect to the existing image compression device which corresponds to an 8 bit depth image.

Backward compatibility is a great advantage. The reason for this is that software corresponding to 8 bits such as a JPEG, or an MPEG, a digital camera, a multifunction terminal with camera, or the like, is widely spread.

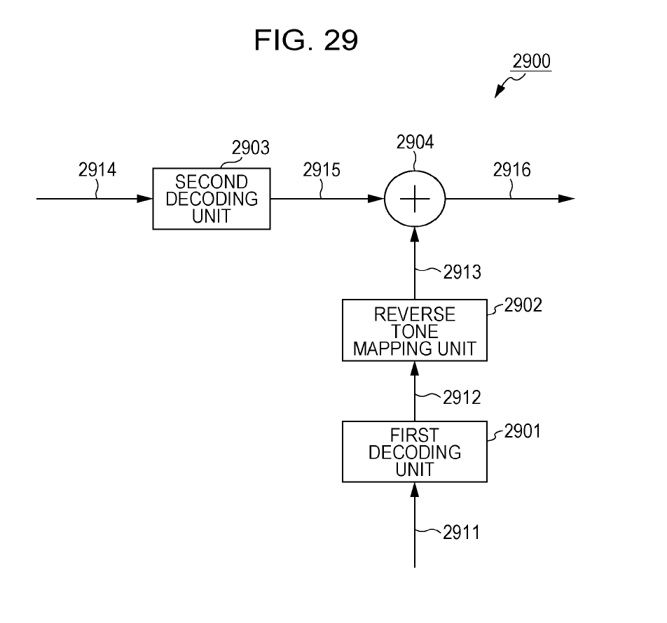

In addition, FIG. 29 illustrates a configuration example of an image decoding device 2900 which decodes a compressed image which is output from the image compression device 2800. The illustrated image decoding device 2900 includes first decoding unit 2901, a reverse tone mapping unit 2902, a second decoding unit 2903, and an addition calculation unit 2904, is configured so as to input the two results of the encoding result 2813 of the high dynamic range image using the first encoding unit 2802, and the encoding result 2817 of the difference image using the second encoding unit 2806, and is also capable of corresponding to the high dynamic range.

The first decoding unit 2901 sets the encoder result using the first encoding unit 2802 on the image compression device 2800 side to an input 2911, performs a decoding process corresponding to a reverse conversion of the encoding process using the first encoding unit 2802, and obtains a decoded image 2912.

The reverse tone mapping unit 2902 performs a process of reverse tone mapping corresponding to a reverse conversion of the tone mapping process using the tone mapping unit 2801 on the image compression device 2800 side with respect to the image 2912 after decoding using the first decoding unit 2901, and outputs a reverse tone mapped image 2913.

Meanwhile, the second decoding unit 2903 sets the encoding result using the second encoding unit 2806 on the image compression device 2800 side to an input 2914, performs a decoding process corresponding to a reverse conversion of the encoding process using the second encoding unit 2806, and obtains a decoded image 2915.

As described above, since the encoding process on the image compression device 2800 side is a non-compressing mode, the image 2913 which is subjected to the reverse tone mapping using the reverse tone mapping unit 2902 does not match the original high dynamic range image 2811 which is input to the image compression device 2800. The addition calculation unit 2904 adds an error component of encoding which is the decoding result 2915 using the second decoding unit 2903 to the image 2913 which is subjected to the reverse tone mapping using the reverse tone mapping unit 2902, generates a high dynamic range image 2916 which is closer to the original state, and sets the image to an output of the image decoding device 2900.

Subsequently, a compressing process of a high dynamic range stereoscopic image will be described. A compressing method of a stereoscopic image has already been standardized as a Multiview Video Coding (PVC) standard in a form of expanding H.264/AVC, for example, and has been put to practical use in a stereoscopic image display in a Blu-ray disc, or the like. Such an international standard may be used also in the embodiment.

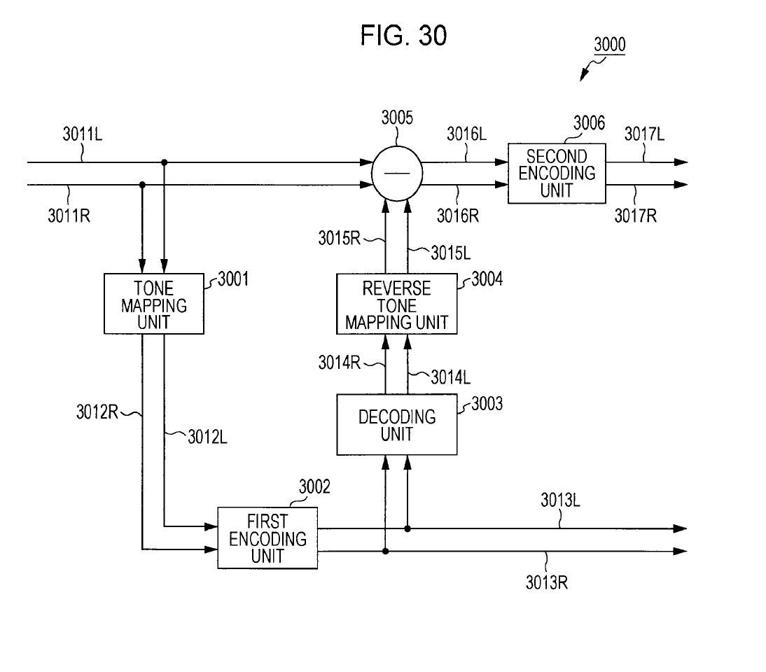

FIG. 30 illustrates another configuration example of an image compression device 3000 in which a high dynamic range image is compressed. The illustrated image compression device 3000 creates a low bit depth image by performing tone mapping, adopts a two-stage encoding method in which a difference between a decoded image thereof and the original image is encoded using a separate encoder (the same as above), and includes a tone mapping unit 3001, a first encoding unit 3002, a decoding unit 3003, a reverse tone mapping unit 3004, a difference calculation unit 3005, and a second encoding unit 3006. In addition, the image compression device 3000 is configured so as to perform a compressing process with respect to a high dynamic range stereoscopic image using a predetermined compression ratio.

The tone mapping unit 3001 performs separate tone mapping with respect to left and right high dynamic range images 3011L and 3011R which are input, and converts the images into 8 bit images of 3012L and 3012R, respectively, for example. It is not necessary for the tone mapping unit 3001 to use a tone mapping method which is particularly different with respect to the left and right images of 3011L and 3011R.

The first encoding unit 3002 performs an encoding process according to a predetermined standard, for example, with respect to the left and right tone mapped images of 3012L and 3012R, and outputs each encoded image 3013L and 3013R.

The decoding unit 3003 respectively performs a decoding process corresponding to a reverse conversion of the encoding process using the first encoding unit 3002 with respect to the left and right encoded images of 3013L and 3013R of the first encoding unit 3002, and obtains left and right decoded images of 3014L and 3014R. When the encoding process using the first encoding unit 3002, and the decoding process using the decoding unit 3003, are reversible modes, the left and right images 3012L and 3012R before encoding, and the left and right images 3014L and 3014R after decoding, respectively completely match; however, usually, both do not match (images 3014L and 3014R after decoding become deteriorated images compared to images 3012L and 3012R before encoding) each other, since compression is not performed in order to improve a compression ratio.

The reverse tone mapping unit 3004 respectively performs a reverse tone mapping process corresponding to a reverse conversion of the tone mapping process using the tone mapping unit 3001 with respect to the images 3014L and 3014R after decoding using the decoding unit 3003.

As described above, since the encoding process in the first encoding unit 3002 is a non-compressing mode, the left and right images of 3015L and 3015R which are subjected to reverse tone mapping using the reverse tone mapping unit 3004 do not match the left and right input images of 3011L and 3011R. The difference calculation unit 3005 respectively calculates differences between the left and right images of 3015L and 3015R which are subjected to reverse tone mapping using the reverse tone mapping unit 3004, and between the left and right input images of 3011L and 3011R, and outputs left and right difference images of 3016L and 3016R.

The second encoding unit 3006 respectively performs an encoding process with respect to the left and right difference images of 3016L and 3016R, and outputs encoded images 3017L and 3017R.

Accordingly, the entire image compression device 3000 performs two ways of output of the left and right encoded images of 3013L and 3013R using the first encoding unit 3002 which corresponds to a usual 8 bit depth image, for example, and encoded images 3017L and 3017R which are difference images (that is, with respect to error in encoding) of respective left and right high dynamic range images.

As such an advantage, for example, it is possible to provide a compressed image with respect to both the existing device which is capable of corresponding only to an 8 bit depth image and the device which is also capable of corresponding to a high dynamic range image, that is, it is possible to have backward compatibility (the same as above).

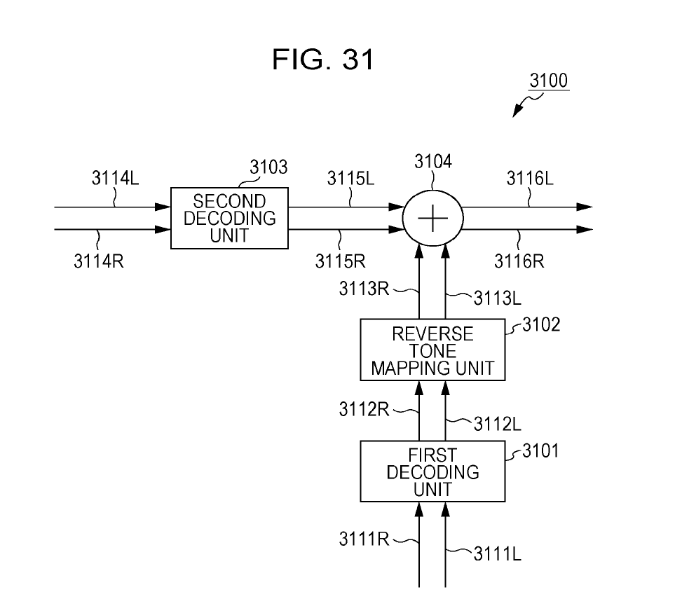

In addition, FIG. 31 illustrates a configuration example of an image decoding device 3100 which decodes a compressed stereoscopic image which is output from the image compression device 3000. The illustrated image decoding device 3100 includes a first decoding unit 3101, a reverse tone mapping unit 3102, a second decoding unit 3103, and an addition calculation unit 3104, is configured so as to input two results of the encoding result 3013 of a high dynamic range stereoscopic image using the first encoding unit 3002, and the encoding result 3017 of the left and right difference images using the second encoding unit 3006, and is capable of corresponding to the high dynamic range.

The first decoding unit 3101 inputs the left and right encoded images of 3111L and 3111R using the first encoding unit 3002 on the image compression device 3000 side, respectively performs a decoding process corresponding to a reverse conversion of the encoding process using the first encoding unit 3002, and obtains left and right decoded images of 3112L and 3112R.

The reverse tone mapping unit 3102 respectively performs reverse tone mapping corresponding to a reverse conversion of the tone mapping process using the tone mapping unit 3001 on the image compression device 3000 side with respect to the left and right decoded images of 3112L and 3112R using the first decoding unit 3101, and outputs left and right reverse tone mapped images of 3113L and 3113R.

Meanwhile, the second decoding unit 3103 inputs left and right encoded images of 3114L and 3114R using the second encoding unit 3006 on the image compression device 3000 side, performs a decoding process corresponding to a reverse conversion of the encoding process using the second encoding unit 3006, and obtains left and right decoded images of 3115L and 3115R.

As described above, since the encoding process on the image compression device 3000 is a non-compressing mode, the left and right reverse tone mapping images of 3113L and 3113R which are output from the reverse tone mapping unit 3102 do not match the original high dynamic range stereoscopic images of 3011L and 3011R which are input to the image compression device 3000. The addition calculation unit 3104 respectively adds the left and right decoded images of 3115L and 3115R using the second decoding unit 3103 to the reverse tone mapped left and right images of 3113L and 3113R using the reverse tone mapping unit 3102, generates high dynamic range stereoscopic images of 3116L and 3116R which are close to the original state, and sets the images as outputs of the image decoding device 3000.

It is also possible to have a configuration in which an image compressing unit is incorporated inside the imaging apparatus 1400, and outputs a code stream by encoding a generated image. As described in the third embodiment, it is possible for one imaging apparatus 1400 to generate a stereoscopic image, and to generate a high dynamic range image, as well.

In addition, it is also possible to configure the imaging apparatus 1400 so as to selectively generate a stereoscopic image or a high dynamic range image based on instructed information from a user or an external device. When information on an instruction of generating a high dynamic range image is input, the image compressing device which is incorporated in the imaging apparatus 1400 may output an encoding result of a high dynamic range image by acting using operation properties which are illustrated in FIG. 28. On the other hand, when information on an instruction of generating a stereoscopic image is input, the image compressing unit which is incorporated in the imaging apparatus 1400 may output an encoding result of a stereoscopic image by acting using operation properties which are illustrated in FIG. 30.

In addition, it is also possible to configure the technology disclosed in the specification as follows.

(1) An imaging apparatus which includes an imaging lens; an imaging element which performs a photoelectric conversion with respect to light which is condensed using the imaging lens; and lens arrays which are configured by arranging micro lenses of which exposure conditions are different on a two-dimensional plane, are arranged by being separated on a front face of an imaging face of the imaging element, and causes light which is output from each micro lens to be formed as an image on the imaging face of the imaging element.
(2) The imaging apparatus which is described in (1) further includes an image composition unit which composites a plurality of imaged images which are output from the imaging element, and of which exposure conditions are different, and generates a high dynamic range image.
(3) The imaging apparatus which is described in (2), in which the lens array includes a micro lens with a property of a low exposure lens, and a micro lens with a property of a high exposure lens, the imaging element photographs a low exposure image and a high exposure image by performing a photoelectric conversion, respectively, with respect to output light of each micro lenses with the property of the low exposure lens, and the property of the high exposure lens, and the image composition unit generates a high dynamic range image by compositing the low exposure image and the high exposure image.
(4) The imaging apparatus which is described in (2), in which the lens array includes micro lenses of three types or more of which exposure lens properties are different, the imaging element photographs images of three types or more of which exposure conditions are different by performing a photoelectric conversion, respectively, with respect to output light of a micro lens with each exposure lens property, and the image composition unit generates a high dynamic range image by compositing imaged images of three types or more of which the exposure conditions are different.
(5) The imaging apparatus which is described in any one of (1) to (4), further includes an interpolation unit which improves resolution by interpolating pixels at a pixel position with another exposure condition using a pixel value of neighboring pixels with the same exposure condition with respect to respective imaged images of which exposure conditions are different, after the images are formed in the imaging element.
(6) The imaging apparatus which is described in (5), in which the interpolation unit improves resolution of respective imaged images of which exposure conditions are different so as to be the same resolution as that of an input image using the pixel interpolation.
(7) The imaging apparatus which is described in any one of (1) to (6), in which the micro lens includes a diaphragm for controlling a light intensity which meets a corresponding exposure condition.
(8) An imaging apparatus which includes an imaging lens; an imaging element which performs photoelectric conversion with respect to light which is condensed using the imaging lens: lens arrays which are configured by being arranged with a plurality of micro lenses to which m×n pixels of the imaging element are respectively allocated on a two-dimensional plane, and are arranged by being separated on a front face of an imaging face of the imaging element; and an image composition unit which composites at least part of image data among m×n pixels which receive light which has passed through each micro lens of the lens array.
(9) The imaging apparatus which is described in (8), in which the image composition unit generates a stereoscopic image based on at least part of image data among the m×n pixels which receive light which has passed through each micro lens of the lens array.
(10) The imaging apparatus which is described in (8), in which the image composition unit composites a left eye image based on image data which is read from a pixel which receives a ray for a left eye which passes through each micro lens, and composites a right eye image based on image data which is read from a pixel which receives a ray for a right eye.
(11) The imaging apparatus which is described in (8), in which the image composition unit generates a plurality of images of which exposure conditions are different at the same time based on at least part of image data among m×n pixels which receive light which has passed through each micro lens of the lens array.
(12) The imaging apparatus which is described in (11), in which the image composition unit generates a low exposure image based on image data which is read from a pixel which is set to a low exposure condition among m×n pixels which receive light which has passed through each micro lens, and generates a high exposure image based on image data which is read from a pixel which is set to a high exposure condition simultaneously with the low exposure image.
(13) The imaging apparatus which is described in (8), in which the image composition unit generates a stereoscopic image, a low exposure image, and a high exposure image at the same time based on at least part of image data among m×n pixels which receive light which has passed through each micro lens of the lens array.
(14) The imaging apparatus which is described in any one of (11) to (13), in which the image composition unit generates a high dynamic range image by compositing the low exposure image and the high exposure image which are generated at the same time.
(15) The imaging apparatus which is described in (8), in which the imaging element is arranged in a state in which a pixel group which is arranged in a square lattice shape along a horizontal direction and a vertical direction is rotated by a predetermined angle in a light receiving plane.
(16) The imaging apparatus which is described in any one of (11) to (13), in which an exposure time of each pixel is controlled so as to have a light intensity which meets each exposure condition.
(17) The imaging apparatus which is described in any one of (11) to (13), in which an amount of narrowing of light which is input to each pixel is controlled so as to be a light intensity which meets each exposure condition.
(18) The imaging apparatus which is described in (13) further including an encoding unit which outputs a code stream by encoding an image which is generated in the image composition unit.
(19) The imaging apparatus which is described in (18), in which generating either a stereoscopic image or a high dynamic range image is selected based on instructed information, and the encoding unit outputs an encoding result of the stereoscopic image when the generating of the stereoscopic image is selected, and outputs an encoding result of the high dynamic range image when the generating of the high dynamic range image is selected.
(20) The imaging apparatus which is described in (19), in which the encoding unit includes a tone mapping unit which performs tone mapping with respect to a high dynamic range image when the high dynamic range image is encoded; a first encoding unit which encodes the image after being subjected to the tone mapping; a decoding unit which decodes an encoding result using the first encoding unit; a reverse tone mapping unit which performs reverse tone mapping with respect to the decoding result using the decoding unit; a difference calculation unit which calculates a difference between the original high dynamic range image and an image which is subjected to the reverse tone mapping; and a second encoding unit which encodes a difference image using the difference calculation unit.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging apparatus comprising:
an imaging lens;
an imaging element which performs a photoelectric conversion with respect to light which is condensed using the imaging lens; and
lens arrays which are configured by arranging micro lenses of which exposure conditions are different on a two-dimensional plane, are arranged by being separated on a front face of an imaging face of the imaging element, and causes light which is output from each micro lens to be formed as an image on the imaging face of the imaging element.

2. The imaging apparatus according to claim 1, further comprising:
an image composition unit which composites a plurality of imaged images which are output from the imaging element, and of which exposure conditions are different, and generates a high dynamic range image.

3. The imaging apparatus according to claim 2,
wherein the lens array includes a micro lens with a property of a low exposure lens, and a micro lens with a property of a high exposure lens,
wherein the imaging element photographs a low exposure image and a high exposure image by performing a photoelectric conversion, respectively, with respect to output light of each micro lenses with the property of the low exposure lens, and the property of the high exposure lens, and
wherein the image composition unit generates a high dynamic range image by compositing the low exposure image and the high exposure image.

4. The imaging apparatus according to claim 2,
wherein the lens array includes micro lenses of three types or more of which exposure lens properties are different,
wherein the imaging element photographs images of three types or more of which exposure conditions are different by performing a photoelectric conversion, respectively, with respect to output light of a micro lens with each exposure lens property, and
wherein the image composition unit generates a high dynamic range image by compositing imaged images of three types or more of which the exposure conditions are different.

5. The imaging apparatus according to claim 1, further comprising:
an interpolation unit which improves resolution by interpolating pixels at a pixel position with another exposure condition using a pixel value of neighboring pixels with the same exposure condition with respect to respective imaged images of which exposure conditions are different, after the images are formed in the imaging element.

6. The imaging apparatus according to claim 5,
wherein the interpolation unit improves resolution of respective imaged images of which exposure conditions are different so as to be the same resolution as that of an input image using the pixel interpolation.

7. The imaging apparatus according to claim 1,
wherein the micro lens includes a diaphragm for controlling a light intensity which meets a corresponding exposure condition.

8. An imaging apparatus comprising:
an imaging lens;
an imaging element which performs photoelectric conversion with respect to light which is condensed using the imaging lens:
lens arrays which are configured by being arranged with a plurality of micro lenses to which m×n pixels of the imaging element are respectively allocated on a two-dimensional plane, and are arranged by being separated on a front face of an imaging face of the imaging element; and
an image composition unit which composites at least part of image data among m×n pixels which receive light which has passed through each micro lens of the lens array.

9. The imaging apparatus according to claim 8,
wherein the image composition unit generates a stereoscopic image based on at least part of image data among the m×n pixels which receive light which has passed through each micro lens of the lens array.

10. The imaging apparatus according to claim 8,
wherein the image composition unit composites a left eye image based on image data which is read from a pixel which receives a ray for a left eye which has passed through each micro lens, and composites a right eye image based on image data which is read from a pixel which receives a ray for a right eye.

11. The imaging apparatus according to claim 8,
wherein the image composition unit generates a plurality of images of which exposure conditions are different at the same time based on at least part of image data among m×n pixels which receive light which has passed through each micro lens of the lens array.

12. The imaging apparatus according to claim 11,
wherein the image composition unit generates a low exposure image based on image data which is read from a pixel which is set to a low exposure condition among m×n pixels which receive light which has passed through each micro lens, and generates a high exposure image based on image data which is read from a pixel which is set to a high exposure condition simultaneously with the low exposure image.

13. The imaging apparatus according to claim 8,
wherein the image composition unit generates a stereoscopic image, a low exposure image, and a high exposure image at the same time based on at least part of image data among m×n pixels which receive light which has passed through each micro lens of the lens array.

14. The imaging apparatus according to claim 11,
wherein the image composition unit generates a high dynamic range image by compositing the low exposure image and the high exposure image which are generated at the same time.

15. The imaging apparatus according to claim 8,
wherein the imaging element is arranged in a state in which a pixel group which is arranged in a square lattice shape along a horizontal direction and a vertical direction is rotated by a predetermined angle in a light receiving plane.

16. The imaging apparatus according to claim 11,
wherein an exposure time of each pixel is controlled so as to have a light intensity which meets each exposure condition.

17. The imaging apparatus according to claim 11,
wherein an amount of narrowing of light which is input to each pixel is controlled so as to be a light intensity which meets each exposure condition.

18. The imaging apparatus according to claim 13, further comprising:
an encoding unit which outputs a code stream by encoding an image which is generated in the image composition unit.

19. The imaging apparatus according to claim 18,
wherein generating either a stereoscopic image or a high dynamic range image is selected based on instructed information, and
wherein the encoding unit outputs an encoding result of the stereoscopic image when the generating of the stereoscopic image is selected, and outputs an encoding result of the high dynamic range image when the generating of the high dynamic range image is selected.

20. The imaging apparatus according to claim 19,
wherein the encoding unit includes
a tone mapping unit which performs tone mapping with respect to a high dynamic range image when the high dynamic range image is encoded;
a first encoding unit which encodes the image after being subjected to the tone mapping;
a decoding unit which decodes an encoding result using the first encoding unit;
a reverse tone mapping unit which performs reverse tone mapping with respect to the decoding result using the decoding unit;
a difference calculation unit which calculates a difference between the original high dynamic range image and an image which is subjected to the reverse tone mapping; and
a second encoding unit which encodes a difference image using the difference calculation unit.
